(19) United States
(12) Patent Application Publication
(10) Pub. No.: US 2026/0114146 A1
(43) Pub. Date: Apr. 23, 2026

(54) ORGANIC LIGHT-EMITTING DEVICE

(71) Applicant: CANON KABUSHIKI KAISHA, Tokyo (JP)

(72) Inventors: SHOMA HINATA, Kanagawa (JP); KOJI ISHIZUYA, Kanagawa (JP); TAKAYUKI ITO, Kanagawa (JP)

(21) Appl. No.: 19/362,076

(22) Filed: Oct. 17, 2025

(30) Foreign Application Priority Data
Oct. 23, 2024 (JP) 2024-186679

(51) Int. Cl. H10K 59/38

(52) U.S. Cl. CPC H10K 59/38

(57) ABSTRACT

A light-emitting device includes a first light-emitting element and a second light-emitting element provided above a surface of a substrate, the second light-emitting element being adjacent to the first light-emitting element. Each of the first light-emitting element and the second light-emitting element includes a first electrode, a light-emitting layer, and a second electrode. The first light-emitting element includes a color filter provided above the second electrode and configured to transmit first light. The second light-emitting element includes a first layer above the second electrode, the first layer having a refractive index less than a refractive index of the color filter and configured to transmit second light. The color filter has a reverse tapered shape in a cross section perpendicular to the surface.

### BACKGROUND

### Field of the Technology

The present disclosure relates to an organic light-emitting device.

### Description of the Related Art

An organic light-emitting device (also referred to also as an organic electroluminescent (EL) device, a light-emitting device, or an organic device) is a light-emitting device composed of a light-emitting element including a pair of electrodes and an organic compound layer including a light-emitting layer between the pair of electrodes. Organic light-emitting devices are known to have a low driving voltage, various light-emitting wavelengths, and high-speed responsiveness and enable thickness and weight reduction in light-emitting devices. Organic light-emitting devices are used in, for example, thin displays, lighting devices, and head-mounted displays (HMDs).

An example of a known light-emitting device includes color filters. For example, each pixel includes red, green, and blue light-emitting materials, and color filters of the respective colors may be formed on the pixels that emit white light, so that the white light is divided to enable a full-color display. An organic light-emitting device including the color filters does not require the formation of organic compound layers for individual light-emitting pixels, so that the density of the light-emitting pixels can be easily increased.

Japanese Patent Laid-Open No. 2023-99337 discusses a light-emitting device having a structure including sub-pixels with color filter layers and sub-pixels with no color filter layers to increase the light extraction efficiency of the light-emitting device.

### SUMMARY

The present disclosure provides a light-emitting device with a high light extraction efficiency.

An aspect of the present disclosure provides a light-emitting device that includes a first light-emitting element and a second light-emitting element provided above a surface of a substrate, the second light-emitting element being adjacent to the first light-emitting element. Each of the first light-emitting element and the second light-emitting element includes a first electrode, a light-emitting layer, and a second electrode. The first light-emitting element includes a color filter provided above the second electrode, and configured to transmit first light. The second light-emitting element includes a first layer above the second electrode, the first layer having a refractive index less than a refractive index of the color filter and configured to transmit second light. The color filter has a reverse tapered shape in a cross section perpendicular to the surface. The first light-emitting element includes a first light-emitting region, and the second light-emitting element includes a second light-emitting region. In the cross section perpendicular to the surface, when a first point is closest to the second light-emitting element and farthest from the surface in the reverse tapered shape of the color filter, a second point is in the first light-emitting region closest to the second light-emitting region and is on the second electrode, a first line passes through the first point parallel to the surface, a second line passes through the first point perpendicular to the surface: n₂/n₁<V₁/(H₁²+V₁²)^{1/2}, with V₁ being a height from an interface between the light-emitting layer and the second electrode in the first light-emitting region to the first line, H₁ being a width from the second point to the second line, n₁ being the refractive index of the color filter, and n₂ being the refractive index of the first layer.

Features of the present disclosure will become apparent from the following description of embodiments with reference to the attached drawings. The following description of embodiments is described by way of example.

### BRIEF DESCRIPTION OF THE DRAWINGS

FIG. 1A is a sectional view of a light-emitting device according to an embodiment.

FIG. 1B is a sectional view of a color filter according to the embodiment.

FIG. 2A is a sectional view of a light-emitting device according to an embodiment.

FIG. 2B is a sectional view of a color filter according to the embodiment.

FIG. 3A is a sectional view of a light-emitting device according to an embodiment.

FIG. 3B is a sectional view of a color filter according to the embodiment.

FIG. 4 is a sectional view of a light-emitting device according to an embodiment.

FIG. 5 is a plan view of a light-emitting device according to an embodiment.

FIG. 6 is a plan view of a light-emitting device according to an embodiment.

FIG. 7 is a plan view of a light-emitting device according to an embodiment.

FIG. 8 is a plan view of a light-emitting device according to an embodiment.

FIG. 9 is a plan view of a light-emitting device according to an embodiment.

FIG. 10 is a plan view of a light-emitting device according to an embodiment.

FIG. 11 is a plan view of a light-emitting device according to an embodiment.

FIG. 12 is a plan view of a light-emitting device according to an embodiment.

FIG. 13 is a plan view of the light-emitting device according to an embodiment.

FIG. 14 is a schematic diagram illustrating an example of a display apparatus according to an embodiment of the present disclosure.

FIG. 15A is a schematic diagram illustrating an example of an imaging apparatus according to an embodiment of the present disclosure.

FIG. 15B is a schematic diagram illustrating an example of an electronic apparatus according to an embodiment of the present disclosure.

FIG. 16A is a schematic diagram illustrating an example of a display apparatus according to an embodiment of the present disclosure.

FIG. 16B is a schematic diagram illustrating an example of a foldable display apparatus.

FIG. 17A is a schematic diagram illustrating an example of a lighting apparatus according to an embodiment of the present disclosure.

FIG. 17B is a schematic diagram illustrating an example of an automobile including a vehicle lamp according to an embodiment of the present disclosure.

FIG. 17C is a schematic diagram illustrating an example of an automobile including a display unit according to an embodiment of the present disclosure.

FIG. 18A is a schematic diagram illustrating an example of a wearable device according to an embodiment of the present disclosure.

FIG. 18B is a schematic diagram illustrating an example of a wearable device including an imaging apparatus according to an embodiment of the present disclosure.

FIG. 19 illustrates an example configuration of a light-emitting device according to a comparative example.

### DESCRIPTION OF THE EMBODIMENTS

In the light-emitting device discussed in Japanese Patent Laid-Open No. 2023-99337, surfaces of color filter layers on which no color filter layers are provided are not specified, and there is room for improvement in terms of the light extraction efficiency.

Embodiments of the present disclosure will now be described in detail with reference to the accompanying drawings. The embodiments described below do not limit the scope of the appended claims. Although the embodiments have a plurality of features, not all of the features are essential to the disclosure, and the features may be combined in any way. In the accompanying drawings, the same or similar structures are denoted by the same reference numerals, and redundant description will be omitted.

Herein, “upper” and “lower” sides of a substrate respectively refer to a side of the substrate adjacent to a first electrode and a side of the substrate opposite to the side adjacent to the first electrode. In addition, when the first electrode is described as being disposed “on” the substrate, contact between the substrate and the first electrode is not necessary.

When a specific light-emitting element 20 of a plurality of color filters is described, it is referred to as, for example, a light-emitting element 20 “R” by attaching an index to the reference numeral. When any one of the light-emitting elements is described, it is referred to simply as an organic light-emitting element “20”. For conciseness, similar nomenclature applies to other components.

### First Embodiment

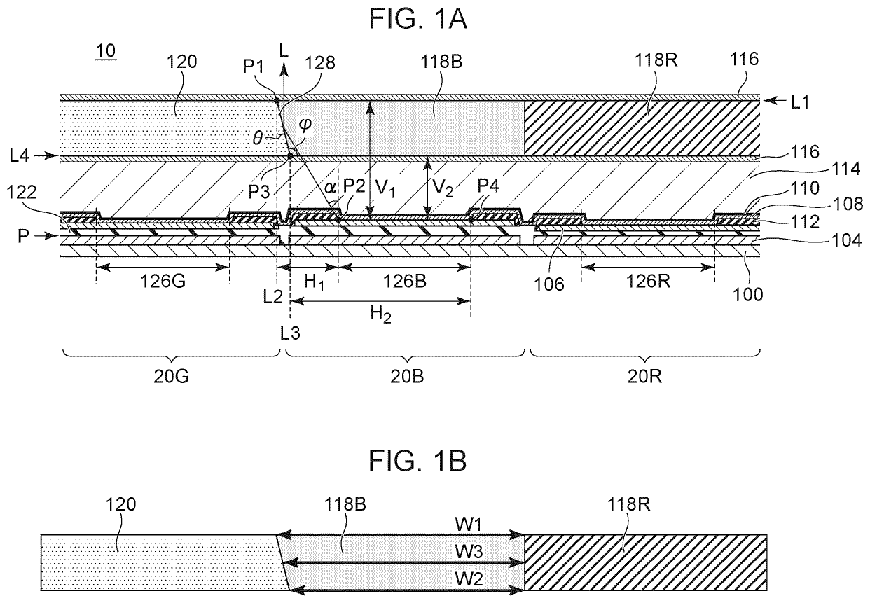

A light-emitting device 10 according to the present embodiment will now be described with reference to FIGS. 1A and 1B. The type of light-emitting elements 20 included in the light-emitting device according to the present disclosure is not particularly limited. A structure including organic light-emitting elements will be described as an example. When the light-emitting device 10 includes organic light-emitting elements, the light-emitting device 10 may be referred to as an organic light-emitting device. FIG. 1A is a schematic sectional view of the light-emitting device 10 according to the present embodiment. FIG. 1B is a schematic sectional view of color filter layers 118 and a first layer 120 according to the present embodiment. The light-emitting device 10 includes the light-emitting elements 20 above a principal surface P of a substrate 100. Each light-emitting element 20 includes a first electrode 106, a light-emitting layer, and a second electrode 110 arranged in that order. The light-emitting layer may have another layer, and a layer including the light-emitting layer disposed between the first electrode 106 and the second electrode 110 is also referred to as an organic compound layer 108. The light-emitting element including the organic compound layer 108 may also be referred to as an organic light-emitting element.

The light-emitting elements 20 included in the light-emitting device 10 may emit light in different colors. For example, the light-emitting elements 20 may include three types of light-emitting elements 20 that emit light in red, green, and blue. In the light-emitting device according to the present embodiment, a light-emitting element 20R, a light-emitting element 20G, and a light-emitting element 20B may be regarded as sub-pixels, and a pixel formed of the light-emitting element 20R, the light-emitting element 20G, and the light-emitting element 20B may be regarded as a single main pixel. The pixel arrangement of the sub-pixels may be, for example, a stripe arrangement, a delta arrangement, or a Bayer arrangement. In particular, the delta arrangement facilitates the arrangement of circular lenses along a display plane. A high-definition display apparatus can be obtained by arranging a plurality of main pixels along a display plane.

The substrate 100 is made of a material capable of supporting the light-emitting elements 20 and other elements above a principal surface P of the substrate 100. More specifically, the substrate 100 may be a semiconductor substrate, such as a silicon substrate, or a resin substrate. Switching elements such as transistors, wiring layers, interlayer insulation films, and other elements may be formed on the substrate 100.

The first electrode 106 is capable of transmitting light emitted from the organic compound layer 108 toward the substrate 100 or reflecting the light emitted from the organic compound layer 108 toward the substrate 100. The first electrode 106 may include one layer or a plurality of layers as long as the first electrode 106 has the desired performance. In particular, when the first electrode 106 includes a layer capable of transmitting light and a layer capable of reflecting light, an insulating layer may be provided between the layer capable of transmitting light and the layer capable of reflecting light. When the insulating layer is provided, each light-emitting element 20 may have an optical resonator structure described below. Alternatively, when the first electrode 106 includes the layer capable of transmitting light and the layer capable of reflecting light, the thickness of the layer capable of transmitting light may be set so that each light-emitting element 20 has an optical resonator structure.

The electrode capable of transmitting the light emitted from the organic compound layer 108 toward the substrate 100 is preferably a transparent electrode, to ensure light emission efficiency. More specifically, the transparent electrode may be a thin film made of a conductive material, for example, a conductive oxide material, such as indium tin oxide (ITO), indium zinc oxide (IZO), aluminum zinc oxide (AZO), or a compound oxide including indium oxide, gallium oxide, and zinc oxide (IGZO); a metal, such as Al, Ag, or Pt; an alloy; or a metal oxide.

The electrode capable of reflecting the light emitted from the organic compound layer 108 toward the substrate 100 preferably has a light reflectance of 70% or more. More specifically, the electrode may be made of a metal material, such as Al, Ag, Pt, Ni, or Ti, an alloy obtained by adding Si, Cu, Ni, Nd, Ti, or the like to the metal material, or a metal compound, such as TiN.

The organic compound layer 108, which is provided on the first electrode 106, may be formed by a method, such as vapor deposition, spin coating, or an inkjet method. The organic compound layer 108 includes at least a light-emitting layer. The light-emitting layer includes at least one light-emitting material that may be, for example, a blue light-emitting material, a green light-emitting material, or a red light-emitting material. The light-emitting material may be a fluorescent material, a delayed fluorescent material, or a phosphorescence material. One light-emitting layer may include one type of light-emitting material or two or more types of light-emitting materials. The light-emitting layer may be composed of one layer or a plurality of layers. When the light-emitting layer includes a plurality of layers, these layers may be provided adjacent to each other or with another layer disposed therebetween. When one light-emitting layer includes two or more types of light-emitting materials, or when the light-emitting layer includes a plurality of layers, the light-emitting layer may emit white light. The light-emitting layer may be made of an inorganic light-emitting material or quantum dots. Alternatively, the light-emitting layer may include light-emitting diodes.

The organic compound layer may include one or more layers other than the light-emitting layer. When the organic compound layer includes layers other than the light-emitting layer, examples of the other layers include a hole injection layer, a hole transport layer, an electron block layer, a hole block layer, an electron transport layer, an electron injection layer, and a charge generation layer. In particular, when the organic compound layer 108 includes a charge generation layer, the light-emitting element 20 may be regarded as an organic light-emitting element having a tandem structure. The light-emitting element 20 having a tandem structure features high light emission efficiency.

The second electrode 110, which is provided on the organic compound layer 108, is made of a material capable of transmitting at least a portion of the light emitted by the organic compound layer 108. More specifically, the material may be a semi-transmissive reflective material formed of a thin film made of a transparent conductive oxide material, such as ITO, IZO, AZO, or IGZO; a metal, such as Al, Ag, or Au; an alkali metal, such as Li or Cs; an alkali earth metal, such as Mg, Ca, or Ba; or an alloy containing these metals. In particular, the second electrode 110 is preferably made of Ag or an alloy of Mg and Ag. The second electrode 110 may be composed of one layer or a plurality of layers as long as the second electrode 110 is capable of transmitting light. The second electrode 110 may also serve as a layer capable of reflecting light. In the present embodiment, the second electrode 110 is provided to extend continuously over plural light-emitting elements 20. However, the second electrode 110 is not so limited.

In the present embodiment, the first electrode 106 may be a negative electrode and the second electrode 110 may be an positive electrode. Alternatively, the first electrode 106 may be an positive electrode and the second electrode 110 may be a negative electrode. In each light-emitting element 20, the positive electrode supplies holes, and the negative electrode supplies electrons. The holes and electrons recombine in the organic compound layer 108, in particular, in the light-emitting layer, so that light is emitted from the light-emitting element 20.

The organic light-emitting element according to the present embodiment may include a metal layer 104 between the substrate 100 and the first electrode 106. The organic light-emitting element according to the present embodiment may also include an insulator portion 112 that covers at least end portions of the first electrode 106. The organic light-emitting element according to the present embodiment may further include at least one of a sealing layer 114, a planarization layer 116, and an optical member 124 above the second electrode 110. The organic light-emitting element according to the present embodiment may further include an insulating layer 122 between the metal layer 104 and the first electrode 106.

When the organic light-emitting element according to the present embodiment includes the metal layer 104 between the substrate 100 and the first electrode 106, the metal layer 104 may function as a reflective layer that reflects the light from the organic compound layer 108 and emits the reflected light toward the second electrode 110. Therefore, the metal layer 104 may also be referred to as a reflective layer.

The metal layer 104 may serve to supply current to the first electrode 106. The metal layer 104 may be connected to a power supply directly or via a wiring layer. Alternatively, current may be supplied from the power supply to the metal layer 104 through a transistor.

Therefore, the metal layer 104 is made of a conductive material, and may have a light reflectance of 70% or more. More specifically, the metal layer 104 may be made of a metal material, such as Al, Ag, Pt, Ni, or Ti, an alloy obtained by adding Si, Cu, Ni, Nd, Ti, or the like to the metal materials, or a metal compound, such as TiN. The metal layer 104 may be composed of one layer or a plurality of layers.

The insulator portion 112 covers at least the end portions of the first electrode 106 and serves to insulate the first electrode 106 from the first electrode 106 of an adjacent organic light-emitting element. An opening 126 is a region of the first electrode 106 that is not covered by the insulator portion 112. The opening 126 may also be referred to as a light-emitting region. The first electrode 106 and the organic compound layer 108 are in contact with each other in the opening 126. The insulator portion 112 may be formed of an inorganic material, such as silicon nitride, silicon oxynitride, or silicon oxide, or an organic material, such as acrylic resin, polyimide resin, epoxy resin, or silicone resin. The insulator portion 112 may be formed by a method such as sputtering or chemical vapor deposition (CVD).

The sealing layer 114, which may be disposed above the second electrode 110, serves to block the entrance of air and moisture to protect the organic light-emitting element. The material of the sealing layer 114 is not particularly limited, but may be a material that transmits light and that is capable of blocking the entrance of oxygen and moisture from the outside. Examples of the material include inorganic materials, such as silicon nitride, silicon oxynitride, silicon oxide, aluminum oxide, and titanium oxide, and organic materials, such as acrylic resin, polyimide resin, epoxy resin, silicone resin, and polyester resin.

The sealing layer 114 may be formed by a method such as CVD, atomic layer deposition (ALD), or sputtering.

The sealing layer 114 may be composed of one layer or a plurality of layers as long as the sealing layer 114 has the above-described function. When the sealing layer 114 is composed of a plurality of layers, the sealing layer 114 may have a multilayer structure including only inorganic materials, only organic materials, or both inorganic and organic materials. For example, the sealing layer 114 may have a multilayer structure including a SiN layer formed by CVD and a high-density layer (for example, an Al₂O₃ layer) formed by ALD. The sealing layer 114 may be formed to extend over a plurality of organic light-emitting elements, or be formed for each organic light-emitting element. The sealing layer 114 may be integrated with a color filter 118 described below. In such a case, the color filter 118 can be accurately formed.

The planarization layer 116 may be formed on the sealing layer 114 and the color filter 118. The planarization layer 116 is provided to reduce the unevenness of an underlying layer. The material of the planarization layer 116 is not particularly limited. The planarization layer 116 may be formed of an inorganic material or an organic material. When the planarization layer 116 is formed of an organic material, the organic material may be a low-molecular-weight material or a high-molecular-weight material.

The planarization layer 116 may be formed by a wet process, such as spin coating, dip coating, slit coating, or blade coating. When a wet process is used, the planarization layer 116 can be easily formed to have a flat light-emission-side surface. The planarization layer 116 formed by a wet process may be cured by, for example, heating or UV radiation. The planarization layer 116 may be formed to extend over a plurality of organic light-emitting elements.

When the planarization layer 116 is provided, the color filter 118 may be formed on the planarization layer 116 by a photolithographic process. Therefore, the color filter 118 can be accurately formed.

The optical member 124 may be provided on a light-emission side of each light-emitting element 20, and may be provided above or below the color filter 118. The optical member 124 may include lenses, and the shape thereof is not particularly limited. The optical member 124 may be convex toward the organic compound layer 108, or be convex in a direction away from the organic compound layer 108. The optical member 124 may also be referred to as microlenses. The microlenses may be spherical microlenses, non-spherical microlenses, or asymmetrical microlenses.

The optical member 124 is made of a material that transmits light. More specifically, for example, the optical member 124 may be made of an organic material, such as acrylic resin, epoxy resin, or silicone resin, or an inorganic material, such as silicon nitride, silicon oxynitride, or silicon oxide.

When the optical member 124 is convex in a direction away from the organic compound layer 108, the region on the light-emission side of the optical member 124 has a refractive index less than that of the material of the optical member 124. In particular, gas, such as air or nitrogen, or a low-refractive-index material, such as silica aerogel, is provided, or the region is in a vacuum state. When the optical member 124 is convex toward the organic compound layer 108, a material with a refractive index less than that of the material of the optical member 124 is disposed in contact with the optical member 124 on the side adjacent to the organic compound layer 108.

The insulating layer 122 is disposed between the metal layer 104 and the first electrode 106. The insulating layer 122 may be made of a material capable of transmitting light. Examples of the material include inorganic materials, such as silicon nitride, silicon oxynitride, and silicon oxide, and organic materials, such as acrylic resin, polyimide resin, epoxy resin, and silicone resin. The insulating layer 122 may be formed by a method such as sputtering or (CVD).

The insulating layer 122 may have a film thickness adjusted to enable efficient extraction of light emitted by the organic compound layer 108. Here, the film thickness is the thickness of a layer in a direction perpendicular to the principal surface in a cross section passing through the substrate 100, the insulating layer 122, and the organic compound layer 108. The film thickness of the insulating layer 122 may be changed to adjust the light emission efficiency and color purity of each of the organic light-emitting elements.

In each organic light-emitting element according to the present embodiment, a portion of the light emitted from the organic compound layer 108 is reflected by the metal layer 104. When the light emitted by the organic compound layer 108 and the reflected light interfere and reinforce each other, the organic light-emitting element according to the present embodiment can be regarded as having an optical resonator structure.

More specifically, the light emitted by the organic compound layer 108 toward the second electrode 110 and a portion of the light emitted from the organic compound layer 108 that is reflected by the metal layer 104 interfere with each other to reinforce each other. Therefore, the organic light-emitting element having an optical resonator structure has high light emission efficiency and high color purity.

The optical resonator structure will now be described. Assume that a first reflective surface is a surface of a reflective layer included in the first electrode 106 or a surface of the metal layer 104. In this case, the optical distance between the first reflective surface and the light-emitting region (light-emitting position) of the organic compound layer 108 can be optimized by satisfying Equation (A), below.

In Equation (A), L, is the optical path length (optical distance) from the first reflective surface to the light-emitting position of the organic compound layer 108, Ør is a phase shift caused when the first reflective surface reflects light with a wavelength 2, and m is an integer of 0 or more. The film thickness between the first electrode 106 and the organic compound layer 108, the film thickness of each layer included in the organic compound layer 108, the film thickness of the insulating layer 122, and the like may be designed to satisfy Equation (A):

$${L}_{r} = ( 2 \times m - ( {Φ}_{r} / π ) ) \times ( λ / 4 ) \qquad ( A )$$

Assume that a second reflective surface is a lower surface of the second electrode 110 (interface between the organic compound layer 108 and the second electrode 110). An optical distance Lₛ from the light-emitting position to the second reflective surface may satisfy Equation (B), below, where Φₛ is a phase shift caused when the second reflective surface reflects light with the wavelength λ and m₂ is an integer of 0 or more.

$${L}_{s} = ( 2 \times {m}_{2} - ( {Φ}_{s} / π ) ) \times ( λ / 4 ) \qquad ( B )$$

Therefore, an optical distance L from the first reflective surface to the second reflective surface may satisfy Equation (C), below. In Equation (C), Φ is the sum of the phase shift Φᵣ and the phase shift Φₛ, and m₃ is an integer of 0 or more.

$$L = {L}_{r} + {L}_{s} = ( 2 \times {m}_{3} - Φ / π ) \times ( λ / 4 ) \qquad ( C )$$

Here, the allowable error range in the above-described Equations (A) to (C) is about ±λ/8 or about ±20 nm. The light-emitting position of the organic compound layer 108 may be difficult to determine, and therefore can be substituted by an interface of the light-emitting layer adjacent to the first reflective surface or an interface of the light-emitting layer adjacent to the second reflective surface in the organic compound layer 108. Considering the above-described allowable error range, the light reinforcing effect can be obtained even when the above substitution is made.

When the light-emitting device according to the present embodiment includes the light-emitting element 20B and the light-emitting element 20G, each of the light-emitting element 20B and the light-emitting element 20G may include the metal layer 104 between the substrate 100 and the first electrode 106. In this case, in a cross section passing through the substrate 100 and the organic compound layer 108, the distance between the first electrode 106 and the metal layer 104 in the light-emitting element 20B may differ from the distance between the first electrode 106 and the metal layer 104 in the light-emitting element 20G. This enables the light-emitting elements 20 included in the light-emitting device according to the present embodiment to have an optical resonator structure. In this case, the insulating layer 122 may be disposed between the reflective layer 104 and the first electrode 106. The first electrode 106 of each light-emitting element may have a different thickness so that the distance between the metal layer 104 and the first electrode 106 varies.

Similarly, when the light-emitting device according to the present embodiment further includes the light-emitting element 20R, the light-emitting element 20R may include the metal layer 104 between the substrate 100 and the first electrode 106. In this case, in a cross section passing through the substrate 100 and the organic compound layer 108, the distance between the first electrode 106 and the metal layer 104 in the light-emitting element 20R may differ from the distance between the first electrode 106 and the metal layer 104 in the light-emitting element 20G. Also, the distance between the first electrode 106 and the metal layer 104 in the light-emitting element 20R may differ from the distance between the first electrode 106 and the metal layer 104 in the light-emitting element 20B. This enables the light-emitting elements 20 included in the light-emitting device according to the present embodiment to have an optical resonator structure. In this case, the insulating layer 122 may be disposed between the reflective layer 104 and the first electrode 106. The first electrode 106 of each light-emitting element may have a different thickness so that the distance between the metal layer 104 and the first electrode 106 varies.

More specifically, when the light-emitting device according to the present embodiment includes the light-emitting element 20B and the light-emitting element 20G, in a cross section passing through the substrate 100, the insulating layer 122, and the organic compound layer 108, each of the light-emitting element 20B and the light-emitting element 20G may include the metal layer 104 between the substrate 100 and the first electrode 106, and the distance between the metal layer 104 and the first electrode 106 included in the light-emitting element 20B may differ from the distance between the metal layer 104 and the first electrode 106 included in the light-emitting element 20G. Similarly, when the light-emitting device according to the present embodiment also includes the light-emitting element 20R, in a cross section passing through the substrate 100, the insulating layer 122, and the organic compound layer 108, the light-emitting element 20R may include the metal layer 104 between the substrate 100 and the first electrode 106, and the distance between the metal layer 104 and the first electrode 106 included in the light-emitting element 20R may differ from the distance between the metal layer 104 and the first electrode 106 included in the light-emitting element 20B. The distance between the metal layer 104 and the first electrode 106 included in the light-emitting element 20R may also differ from the distance between the metal layer 104 and the first electrode 106 included in the light-emitting element 20G. This enables the light-emitting elements 20 included in the light-emitting device according to the present embodiment to have an optical resonator structure.

When the light-emitting device according to the present embodiment includes the light-emitting element 20B and the light-emitting element 20G, in a cross section passing through the substrate 100 and the organic compound layer 108, each of the light-emitting element 20B and the light-emitting element 20G may include the metal layer 104 between the substrate 100 and the first electrode 106, and the distance between the metal layer 104 and the light-emitting layer included in the light-emitting element 20B may differ from the distance between the metal layer 104 and the light-emitting layer included in the light-emitting element 20G. Similarly, when the light-emitting device according to the present embodiment further includes the light-emitting element 20R, in a cross section passing through the substrate 100, the insulating layer 122, and the organic compound layer 108, the light-emitting element 20R may include the metal layer 104 between the substrate 100 and the first electrode 106, and the distance between the metal layer 104 and the light-emitting layer included in the light-emitting element 20B may differ from the distance between the metal layer 104 and the light-emitting layer included in the light-emitting element 20R. The distance between the metal layer 104 and the light-emitting layer included in the light-emitting element 20B may also differ from the distance between the metal layer 104 and the light-emitting layer included in the light-emitting element 20G. In this case, the first electrodes 106 included in the light-emitting element 20R, the light-emitting element 20G, and the light-emitting element 20B may have different thicknesses. This also enables the light-emitting elements 20 included in the light-emitting device according to the present embodiment to have an optical resonator structure. In addition, the light-emitting elements 20 included in the light-emitting device according to the present embodiment can have an optical resonator structure even when the insulating layer 122 is not provided between the metal layer 104 and the first electrode 106.

In the light-emitting device according to the present embodiment, whereas the light-emitting elements 20 include the color filters 118 on the light-emission side, at least one of the light-emitting elements 20 includes the first layer 120 having a refractive index less than that of the color filters 118. More specifically, a first organic light-emitting element includes a color filter that is provided above a second electrode and that transmits first light. A second organic light-emitting element includes a first layer that is provided above a second electrode, that transmits second light, and that has a refractive index less than that of the color filter. The color filters 118 and the first layer 120 may be provided on the sealing layer 114 or the planarization layer 116. The color filters may be formed directly on the substrate 100. Alternatively, the color filters 118 may be formed on a substrate different from the substrate 100, and the substrate on which the color filters 118 is formed may be bonded to the sealing layer 114.

Each color filter 118 transmits light in a desired wavelength range and absorbs light in an unnecessary wavelength range, thus enabling emission of light with high color purity, so that a high-quality display can be achieved.

The first layer 120, which is a layer having a refractive index less than that of the color filters 118, transmits light in a desired wavelength range. The first layer 120 may be a layer made of transparent resin (transparent resin layer), a layer of air (air layer), or a color filter. The first layer 120 is may be a transparent resin layer or an air layer because, in such a case, the transmittance of light emitted from the light-emitting element 20 is higher than when a color filter is used. When the first layer 120 is a transparent resin layer or an air layer, the light extraction efficiency can be further increased. The transparent resin refers to a resin capable of transmitting 80% or more of the light emitted from the light-emitting element 20. The air layer refers to a layer in which no color filter or transparent resin is provided in the same layer as the color filters 118.

The color of light emitted by the light-emitting element 20 including the first layer 120 is not particularly limited. Light having an emission peak in a light-emitting region with high visibility may be transmitted, for example light having an emission peak in the range of 490 nm or more and 550 nm or less (green light) is transmitted for display quality, because a reduction in color purity is less visually recognizable for light having an emission peak in a light-emitting region with high visibility. Here, the emission peak is one of the emission peaks in the visible light region that has the highest intensity.

The light-emitting device according to the present embodiment includes the light-emitting element 20B and the light-emitting element 20G. The light-emitting element 20B and the light-emitting element 20G may be organic light-emitting elements that are adjacent to each other. In the present embodiment, the light-emitting element 20B and the light-emitting element 20G are adjacent to each other. The light-emitting element 20B includes the color filter 118B, and the light-emitting element 20G includes the first layer 120.

The light-emitting device according to the present embodiment may further include the light-emitting element 20R. The light-emitting element 20R includes the color filter 118R. In this case, the color filter 118R and the color filter 118B may be color filters that transmit light of the same color, or color filters that emit light of different colors. For example, the color filter 118R may transmit red light, and the color filter 118B may transmit blue light.

In embodiments described below, the centers of the openings 126 overlap the centers of the color filters 118 and the first layer 120 in an orthogonal projection on the substrate. However, the arrangement is not so limited. To increase the light extraction efficiency in a specific direction, the centers of the openings 126 may be shifted from the centers of the color filters 118 and the first layer 120.

In this case, the centers of the openings 126 may be shifted from the centers of the color filters 118 and the first layer 120 in all of the light-emitting elements 20 included in the light-emitting device 10. Alternatively, the centers of the openings 126 may overlap the centers of the color filters 118 and the first layer 120 in the organic light-emitting elements in a central area of the display region of the light-emitting device 10, while the centers of the openings 126 are shifted from the centers of the color filters 118 and the first layer 120 in the organic light-emitting elements near the periphery of the display region. In this case, the centers of the openings 126 may be shifted from the centers of the color filters 118 and the first layer 120 by a greater amount in the organic light-emitting elements closer to the periphery of the display region. In addition, in this case, the centers of the color filters 118 and the first layer 120 may be shifted from the centers of the openings 126 in directions toward the periphery of the light-emitting device 10.

In the present embodiment, the color filter 118B of the light-emitting element 20B has a reverse tapered shape. The reverse tapered shape is a shape in which, in a cross section perpendicular to the principal surface P, an angle of a corner of the color filter 118 formed between the principal surface P and a side surface 128 of the color filter 118 is greater than 90 degrees and less than 180 degrees. More specifically, referring to FIG. 1A, the reverse tapered shape is a shape in which an angle φ is greater than 90 degrees and less than 180 degrees. Here, the side surface 128 of the color filter 118 is the side surface adjacent to the first layer 120.

Referring to FIG. 1B, in the cross section perpendicular to the principal surface P, a width of the color filter 118 along the top surface of the color filter 118 is defined as a first width W1, a width of the color filter 118 along the bottom surface of the color filter 118 is defined as a second width W2, and a width of the color filter 118 at a position between the top and bottom surfaces of the color filter 118 is defined as a third width W3. In this case, the color filter of the light-emitting device according to the present embodiment satisfies the following relationship: W1>W3>W2. The third width W3 may be measured along a plane substantially parallel to the principal surface P or parallel to the principal surface P. This also applies to other embodiments.

In each of the embodiments, the width of the color filter 118 at a position between the top and bottom surfaces of the color filter 118 may satisfy the relationship of W1>W3>W2 at least in a portion of the region between the top and bottom surfaces of the color filter 118, but may satisfy the relationship of W1>W3>W2 over the entire region between the top and bottom surfaces of the color filter 118.

In the present embodiment, of the light emitted from the organic compound layer 108B, light L that is incident on the side surface 128B of the color filter 118 at an angle greater than or equal to a critical angle is totally reflected by the side surface 128B of the color filter 118. Since the side surface of the color filter 118 has a reverse tapered shape, the minimum value of an emission angle α of the light L emitted from the organic compound layer 108B, incident on the side surface 128 of the color filter 118B, and totally reflected by the side surface 128 is reduced by an angle θ. As a result, of the light emitted from the organic compound layer 108B, the light L that is incident on the side surface 128B of the color filter 118B at an angle greater than or equal to the critical angle can be at least partially extracted in the forward direction. Here, the angle θ may be expressed as θ=φ−90 (degrees).

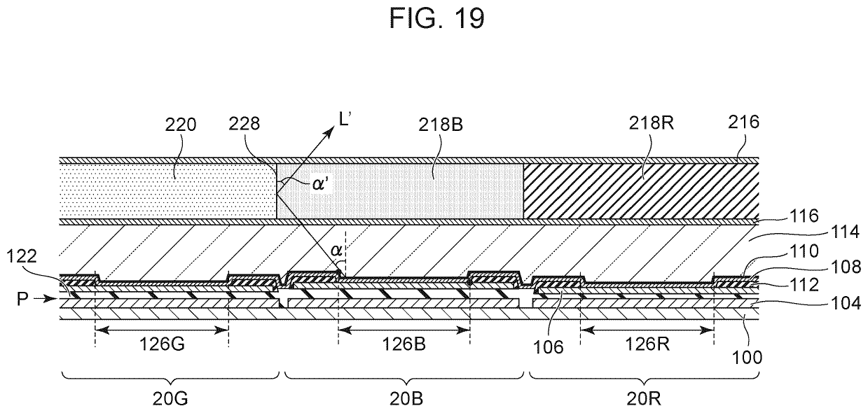

Comparison between the light-emitting device according to the present embodiment and the organic light-emitting device discussed in Japanese Patent Laid-Open No. 2023-99337, or a comparative example, will now be discussed. FIG. 19 is a sectional view of an organic light-emitting device according to the comparative example. In the organic light-emitting device illustrated in FIG. 19, a side surface 228 of a color filter 218 and a side surface of a first layer 220 are perpendicular to the principal surface P. As a result, of the light emitted from the light-emitting layer 108B of the light-emitting element 20B, light L′ incident on the side surface 228 of the color filter 218B at an angle greater than or equal to a critical angle is totally reflected. Since the color filter 218B does not have a reverse tapered shape, angles α and α′ are equal in FIG. 19. As a result, of the light emitted from the light-emitting layer 108B included in the light-emitting element 20B, the light L′ incident on the side surface 228 of the color filter 218B at an angle greater than or equal to the critical angle cannot be extracted in the forward direction.

As described above, the light-emitting device according to the present embodiment has a light condensing effect due to the color filter 118 having a reverse tapered shape, and therefore has a higher light extraction efficiency than the organic light-emitting device according to the comparative example.

In the light-emitting device according to the present embodiment and other embodiments described below, a refractive index n₁ of the color filter 118 and a refractive index n₂ of the first layer 120 satisfy the relationship described below.

<Relationship Between Refractive Index n₁ of Color Filter 118 and Refractive Index n₂ of First Layer 120>

Assume that n₁ is a refractive index of the color filter 118B and n₂ is a refractive index of the first layer 120. The difference between the refractive index n₁ of the color filter 118B and the refractive index n₂ of the first layer 120 may be such that the light emitted from the organic compound layer 108B and incident on the side surface 128 of the color filter 118B can be totally reflected. More specifically, n₁−n₂≥0.2 or n₁−n₂>0.2 may be satisfied.

For example, when n₁=1.5 and n₂=1.3, since a critical angle θ_{c} may be expressed as θ_{c}=Arcsin (n₂/n₁), light incident on the side surface 128 of the color filter 118 at an angle greater than or equal to 60 degrees can be totally reflected. As a result, an organic light-emitting device with a high light extraction efficiency can be obtained.

The refractive index n₁ of the color filter 118B and the refractive index n₂ of the first layer 120 satisfy the relationship described below. Points and lines are illustrated in FIGS. 1A to 3B.

The light-emitting element 20B is a light-emitting element including the color filter 118, and the light-emitting element 20G is a light-emitting element including the first layer 120. In the cross section perpendicular to the principal surface P, a first point P1 is on the reverse tapered shape of the color filter 118B, farthest from the principal surface P. A point P2 is on the opening 126B that is closest to the opening 126G. A first line L1 passes through the first point P1 and parallel to the principal surface P. A second line L2 passes through the first point P1 and perpendicular to the principal surface P. V₁ is a height from the second point P2 to the first line L1. H₁ is a width from the second point P2 to the second line L2. Here, V₁ may be a height from the intersection between the line passing through the second point P2 and perpendicular to the principal surface P and the second electrode 110 to the first line L1.

When the side surface 128 of the color filter 118 does not have a reverse tapered shape and is perpendicular to the principal surface P, light emitted from the organic compound layer 108 is totally reflected at the first point P1 when Equation (1), below, is satisfied:

$${n}_{2} / {n}_{1} < {V}_{1} / {( {H}_{1}^{2} + {V}_{1}^{2} )}^{1 / 2} \qquad ( 1 )$$

Therefore, in the present embodiment, the above Equation (1) is also preferably satisfied so that the light extraction efficiency can be increased.

In the example described above, it is assumed that all of the layers through which light travels from the organic compound layer 108 to the color filter 118 have a refractive index of n₁. However, this does not imply any limitation. A layer having a refractive index n₃ different from the refractive index n₁ of the color filter 118 may be disposed between the organic compound layer 108 and the color filter 118. In particular, when n₃>n₁, the light-emitting device according to the present embodiment preferably satisfies Equation (1), above.

### <Angle θ Formed by Side Surface 128 of Color Filter 118 and Principal Surface P of Substrate>

The preferred range of the angle θ formed by the side surface 128 of the color filter 118 and the principal surface P will now be described. The points and lines are illustrated in FIGS. 1A to 3B.

The light-emitting element 20B is an organic light-emitting element including the color filter 118, and the light-emitting element 20G is an organic light-emitting element including the first layer 120. In the cross section perpendicular to the principal surface P, the first point P1 on the reverse tapered shape of the color filter 118 is farthest from the principal surface P. A third point P3 on the reverse tapered shape of the color filter 118 is closest to the principal surface P is defined as a third point P3. A fourth point P4 on the opening 126B is farthest from the opening 126G. The second line L2 passes through the first point P1, perpendicular to the principal surface P. A third line L3 passes through the third point P3, perpendicular to the principal surface P. A fourth line L4 passes through the third point, parallel to the principal surface P. V₂ is a height from the fourth point P4 to the fourth line L4. H₂ is a width from the fourth point P4 to the third line L3. An angle between a straight line connecting the first point P1 and the third point P3 and the second line L2 is a taper angle θ of the color filter 118B. Here, V₂ may be a height from the intersection between the line passing through the fourth point P4 and perpendicular to the principal surface P and the second electrode 110 to the fourth line L4.

Light emitted from the fourth point P4 reaches the third point P3 when Equation (2), below, is satisfied. More preferably, Expression (2-1) is satisfied:

$$θ \leq Arctan ( {H}_{2} / {V}_{2} ) \qquad ( 2 )$$

$$θ < Arctan ( {H}_{2} / {V}_{2} ) \qquad ( 2 - 1 )$$

When Equation (2) is satisfied, light emitted from the fourth point P4 can reach the third point P3. Therefore, in the organic light-emitting device that satisfies Equation (2), light emitted from the organic compound layer 108 can reach a reverse-tapered-shaped portion of the side surface 128 of the color filter 118. Therefore, the above Equation (2) is preferably satisfied, so that the light extraction efficiency can be further increased.

The conditions under which light emitted from the fourth point P4 is totally reflected at the third point P3 and extracted in the forward direction will now be described. When 2θ=Arctan (H₂/V₂) is satisfied, the light emitted from the fourth point P4 can be totally reflected at the third point P3 and extracted in the forward direction. Therefore, when Equation (3) or Expression (3-1) given below, is satisfied, light emitted from the organic compound layer 108 can reach the reverse-tapered-shaped portion and be totally reflected and extracted in the forward direction. Therefore, to increase the light extraction efficiency, the light-emitting device according to the present embodiment preferably satisfies Equation (3):

$$2 θ \leq Arctan ( {H}_{2} / {V}_{2} ) \qquad ( 3 )$$

$$2 θ < Arctan ( {H}_{2} / {V}_{2} ) \qquad ( 3 - 1 )$$

### Second Embodiment

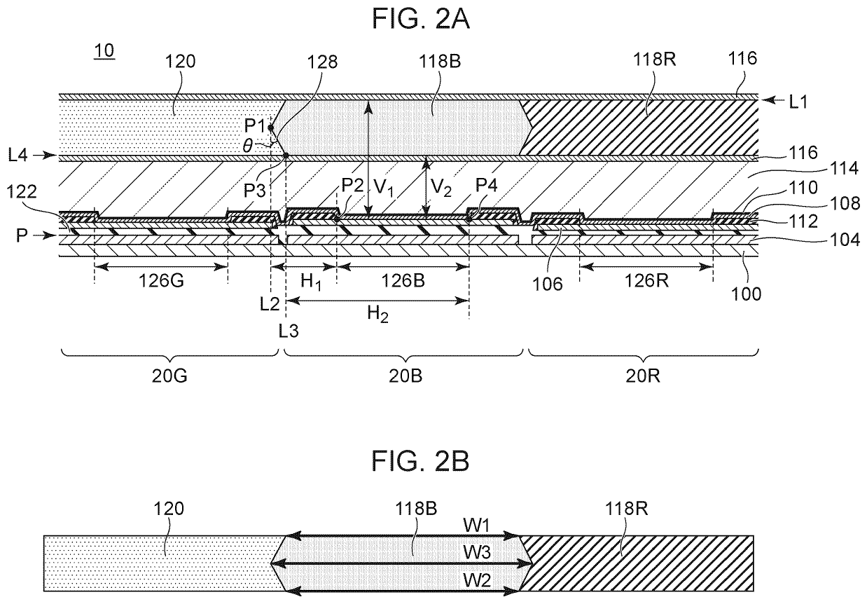

A light-emitting device according to the present embodiment will be described with reference to FIGS. 2A and 2B. FIG. 2A is a schematic sectional view of a light-emitting device 10 according to the present embodiment. FIG. 2B is a schematic sectional view of a color filter layer 118 and a first layer 120 according to the present embodiment. The light-emitting device according to the present embodiment differs from the organic light-emitting device according to the first embodiment in that the color filter 118 has both a tapered shape and a reverse tapered shape.

Referring to FIG. 2B, in a cross section perpendicular to the principal surface P, a first width W1 of the color filter 118 extends along the top surface of the color filter 118, a second width W2 of the color filter 118 extends along the bottom surface of the color filter 118, and a third width W3 of the color filter 118 extends between the top and bottom surfaces of the color filter 118. In this case, the light-emitting device according to the present embodiment satisfies the following relationship: W3>W1, and W3>W2.

Also in the light-emitting device according to the present embodiment, the color filter 118 has a reverse tapered shape, and therefore the light extraction efficiency can be increased.

### Third Embodiment

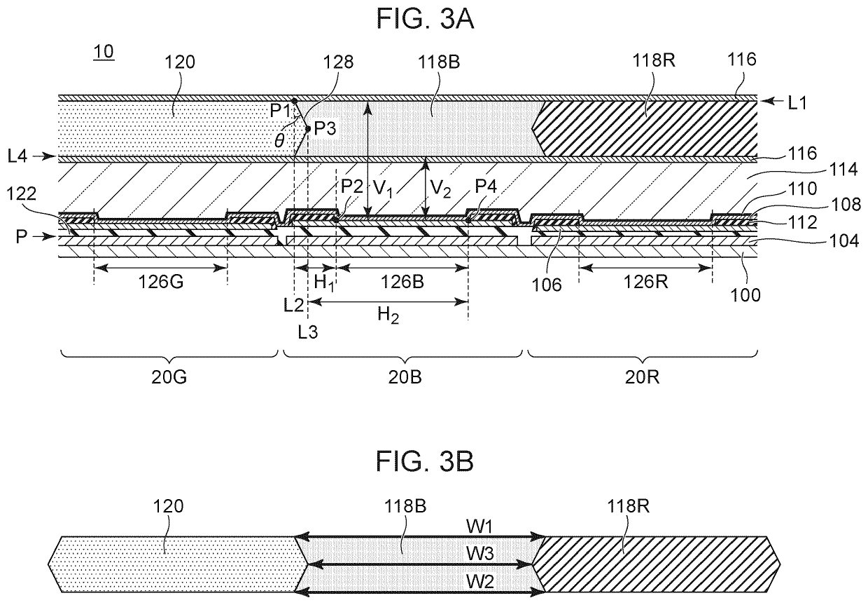

A light-emitting device according to the present embodiment will be described with reference to FIGS. 3A and 3B. FIG. 3A is a schematic sectional view of a light-emitting device 10 according to the present embodiment. FIG. 3B is a schematic sectional view of a color filter layer 118 and a first layer 120 according to the present embodiment. The light-emitting device according to the present embodiment differs from the organic light-emitting device according to the first embodiment in that the color filter 118 has both a tapered shape and a reverse tapered shape.

Referring to FIG. 3B, in a cross section perpendicular to the principal surface P, a first width W1 of the color filter 118 extends along the top surface of the color filter 118, a second width W2 of the color filter 118 extends along the bottom surface of the color filter 118, and a third width W3 of the color filter 118 extends between the top and bottom surfaces of the color filter 118. In this case, the light-emitting device according to the present embodiment satisfies the following relationship: W1>W3 and W2>W3.

Also in the light-emitting device according to the present embodiment, the color filter 118 has a reverse tapered shape, and therefore the light extraction efficiency can be increased.

### Fourth Embodiment

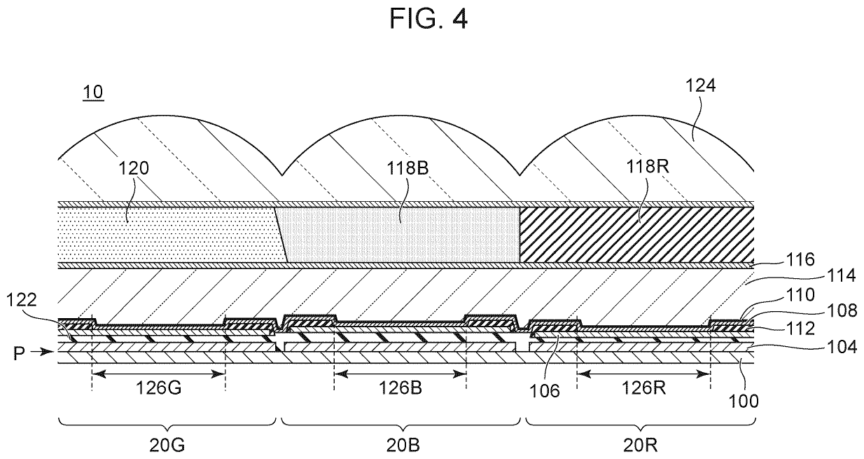

A light-emitting device according to the present embodiment will be described with reference to FIG. 4. FIG. 4 is a schematic sectional view of a light-emitting device 10 according to the present embodiment. The light-emitting device according to the present embodiment differs from the light-emitting device according to the first embodiment in that an optical member 124 is provided. The optical member 124 may also be provided in the organic light-emitting devices according to other embodiments.

The optical member 124 may also be referred to as microlenses. In the present embodiment, the optical member 124 includes convex portions that are convex in a direction away from a principal surface of a substrate 100. Light emitted from an organic compound layer 108 toward the optical member 124 is refracted by a surface of the optical member 124, thereby being converted into parallel light (collimated light). As a result, the light emitted from the organic compound layer 108 can be extracted in the forward direction (direction perpendicular to the principal surface P). In other words, in the present embodiment, the optical member 124 may serve as a collimator. The optical member 124 may have a light-condensing property, and may have a positive power for converting the light emitted from the organic compound layer 108 into parallel light or convergent light.

The optical member 124 is provided on a planarization layer 116 in the present embodiment, but is not so limited. It is not necessary that the planarization layer 116 be provided between the optical member 124 and a color filter 118, and the optical member 124 and the color filter 118 may be integrated together. The optical member 124 may be in contact with the sealing layer 114, and the optical member 124 and the sealing layer 114 may be integrated together. When the optical member 124 and the sealing layer 114 are integrated together, the distance from the optical member 124 to the organic compound layer 108 is less than when the optical member 124 is formed on another substrate and bonded to the sealing layer 114 such that the optical member 124 faces the sealing layer 114. As a result, the solid angle of the light emitted from the organic compound layer 108 and incident on the optical member 124 can be increased, and the light extraction efficiency is increased. In addition, when the optical member 124 and the sealing layer 114 are integrated together, the apices of the optical member 124 can be accurately positioned with respect to the organic compound layer 108. In addition, when the color filter 118, the optical member 124, and the sealing layer 114 are integrated together, the organic compound layer 108, the color filter 118, and the optical member 124 can be accurately positioned with respect to each other.

The order in which the color filter 118 and the optical member 124 are arranged may be selected as appropriate. In the structure illustrated in FIG. 4, the color filter 118 and the optical member 124 are arranged in that order from the substrate 100. In this structure, light emitted from the organic compound layer 108 passes through the color filter 118 before entering the optical member 124. Thus, light that causes a reduction in color purity (light emitted from the organic compound layer 108 at a large emission angle) passes through the color filter 118 over a relatively large distance. As a result, the light-emitting device according to the present embodiment can further suppress the reduction in color purity when the light-emitting device 10 is viewed at an angle.

The color filter 118 and the optical member 124 may be formed on a support substrate different from the substrate 100, and the light-emitting device 10 may be produced by bonding the support substrate to the substrate 100 having the organic compound layer 108 such that the color filter 118 and the optical member 124 face the substrate 100. When the color filter 118 and the optical member 124 are formed separately from the organic compound layer 108, the color filter 118 and the optical member 124 may be formed by a processing method with more flexibility (for example, at a more flexible temperature), and the color filter 118 and the optical member 124 can be designed with more flexibility. The color filter 118 and the optical member 124 may be formed continuously on a single support substrate. Alternatively, the color filter 118 and the optical member 124 may be formed on different support substrates.

The color filter 118 and the optical member 124 may, for example, be bonded to the substrate 100 by a bonding member, such as an adhesive. The bonding member may be disposed on the planarization layer 116. Alternatively, the bonding member may be disposed on the sealing layer 114 without the planarization layer 116 provided therebetween. The optical member 124 may be formed on a support substrate different from the substrate 100, and the support substrate may be bonded to the substrate 100 having the organic compound layer 108 such that the optical member 124 faces the substrate 100. In this case, the optical member 124 may be fixed to the substrate 100 with a bonding member, such as an adhesive, at end portions of the light-emitting device 10 so that a space is provided between the optical member 124 and the sealing layer 114 (or the color filter 118). In this case, the space may be filled with resin. The resin may have a refractive index less than the refractive index of the optical member 124.

The optical member 124 may be formed by an exposure process and a developing process

More specifically, a film of the material of the optical member 124 (for example, a photoresist film) is formed, and the photoresist film is subjected to exposure and development using a mask with continuous gradation. The mask used to form the optical member 124 may be a gray mask. Alternatively, the mask used to form the optical member 124 may be an area gradation mask that enables irradiation of an imaging plane with light having continuous gradation by changing the density distribution of dots in a light shielding film with a resolution less than or equal to the resolution of an exposure device. The optical member 124 formed by the exposure process and the developing process may be etched back to adjust the lens shape. As described above, the optical member 124 includes convex portions that are convex in a direction away from the principal surface P of the substrate 100. The convex portions of the optical member 124 may be portions of substantially spherical (circular) surfaces or non-spherical surfaces.

In the present embodiment, the centers of the openings 126 overlap the apices of the optical member 124 in an orthogonal projection on the substrate 100. However, the arrangement is not so limited. To increase the light extraction efficiency in a specific direction, the centers of the openings 126 may be shifted from the centers of the apices of the optical member 124. The direction of shift may be the same over the entire region in which the light-emitting elements 20 are arranged in the light-emitting device 10. Alternatively, the centers of the openings 126 may overlap the apices of the optical member 124 in a central area of the display region in which the light-emitting elements 20 are arranged in the light-emitting device 10, while the centers of the openings 126 are shifted from the apices of the optical members 124 by a greater amount in organic light-emitting elements closer to the periphery of the display region. In this case, the apices of the optical member 124 may be shifted from the centers of the opening 126 in directions toward the outer periphery of the light-emitting device 10.

### Fifth Embodiment

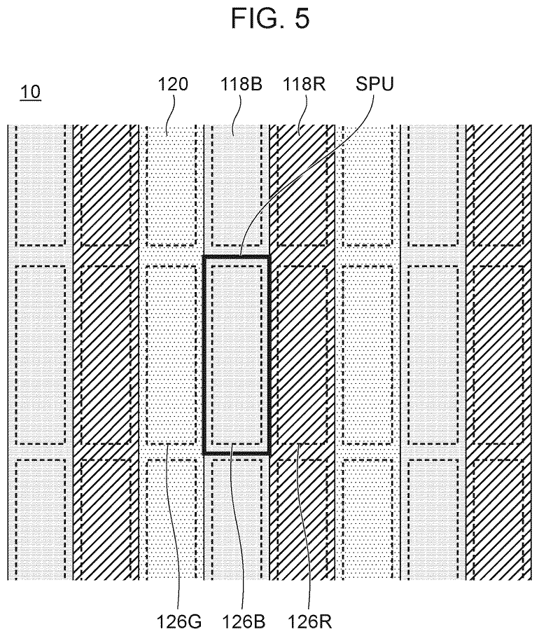

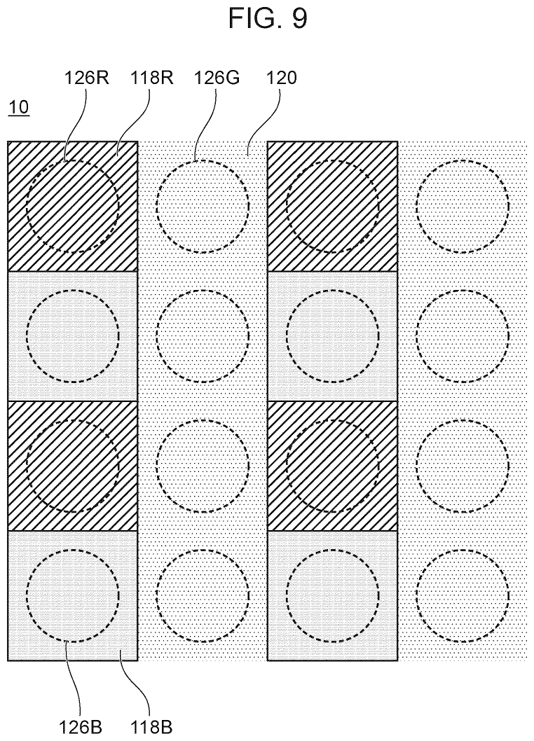

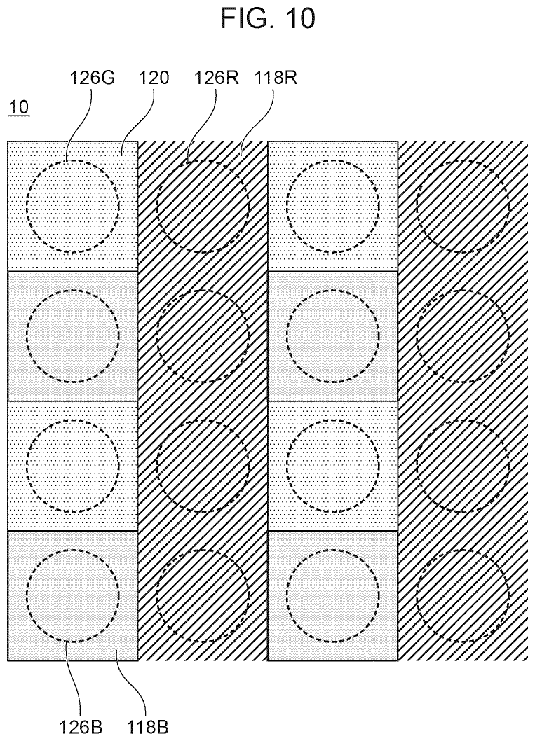

Preferred arrangements of color filters 118 and first layers 120 will be described with reference to FIGS. 5 to 13. FIGS. 5 to 13 are plan views of a light-emitting device 10 that may be applied to the first to fourth embodiments.

As described above, in an organic light-emitting device according to the present disclosure, one of the side surfaces of a color filter that is in contact with a first layer has a reverse tapered shape to increase the light extraction efficiency. Therefore, the light extraction efficiency can be further increased by increasing the ratio of the region in which the color filter 118 is in contact with the first layer 120.

In the light-emitting device 10 illustrated in FIG. 5, light-emitting elements 20R, light-emitting elements 20B, and light-emitting elements 20G, which are sub-pixels, respectively include color filters 118R, color filters 118B, and first layers 120 in a stripe arrangement. In FIG. 5, the color filters 118R, the color filters 118B, and the first layers 120 have an elongated shape. In the present embodiment, a sub-pixel unit SPU, which corresponds to one light-emitting element 20, has an aspect ratio of 3:1, and a plurality of light-emitting elements 20 are arranged below each of the color filters 118 and the first layers 120. In other words, each of the color filters 118 and the first layers 120 is shared by a plurality of light-emitting elements 20.

In the light-emitting device 10 illustrated in FIG. 5, of the side surfaces of a portion of each color filter 118 belonging to one sub-pixel unit SPU, the side surface in contact with the corresponding first layer 120 constitutes ⅜, that is, 37.5% of the entire perimeter along the side surfaces of the sub-pixel unit SPU.

The side surfaces of the color filters 118 and the first layers 120 can be defined as surfaces, other than the top and bottom surfaces of the color filters 118 and the first layers 120. The top surfaces of the color filters 118 and the first layers 120 are surfaces of the color filters 118 and the first layers 120 farthest from the principal surface P. The bottom surfaces of the color filters 118 and the first layers 120 are surfaces of the color filters 118 and the first layers 120 closest to the principal surface P. The top and bottom surfaces of the color filters 118 and the first layers 120 may be substantially parallel to the principal surface P. When the color filters and the first layers have rounded corners as a result of shape variations due to manufacturing or the like, portions of the surfaces that are substantially perpendicular to the principal surface P may be regarded as side surfaces. This also applies to the embodiments described below.

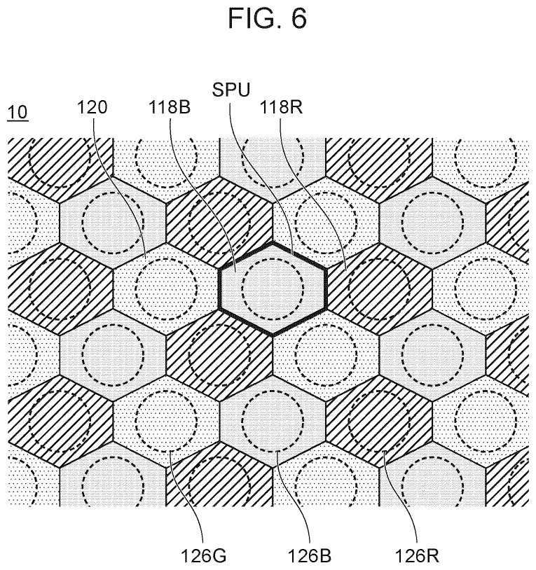

In the light-emitting device 10 illustrated in FIG. 6, light-emitting elements 20R, light-emitting elements 20B, and light-emitting elements 20G, which are sub-pixels, respectively include color filters 118R, color filters 118B, and first layers 120 in a delta arrangement. In this case, in a plan view relative to the principal surface P, each of the color filters 118R, the color filters 118B, and the first layers 120 has a hexagonal outer shape, which is substantially the same shape as the shape of a sub-pixel unit SPU corresponding to one light-emitting element 20. Each side of the sub-pixel unit SPU can be regarded as a collection of points at which the distance from the center of one opening 126 and the distance from the center of an adjacent opening 126 are equal.

When the color filters 118 and the first layers 120 are in a delta arrangement, 50% or more of the side surfaces of the color filters 118R and the color filters 118B are in contact with the first layers 120. Thus, the color filters 118 and the first layers 120 in a delta arrangement provide a ratio of the region in which the color filters 118 are in contact with the first layers 120 greater than when the color filters 118 and the first layers 120 are in a stripe arrangement.

To increase the light extraction efficiency, of the side surfaces of the color filters 118, the ratio of the side surfaces in contact with the first layers 120 may be 37.5% or more, preferably 40% or more, more preferably 50% or more, and still more preferably 60% or more.

The arrangement of the color filters 118 and the first layers 120 is not limited to those illustrated in FIGS. 5 and 6. Each color filter 118 preferably has more than one side surface in contact with the first layers 120. With such a structure, the light extraction efficiency can be further increased.

More specifically, an organic light-emitting device includes a first organic light-emitting element, a second organic light-emitting element, and a third organic light-emitting element. The first organic light-emitting element and the second organic light-emitting element are adjacent to each other, and the first organic light-emitting element and the third organic light-emitting element are adjacent to each other. The first organic light-emitting element includes a color filter that transmits first light. The second organic light-emitting element includes a first layer that transmits second light and that has a refractive index less than that of the color filter. The third organic light-emitting element includes a second layer that transmits third light and that has a refractive index less than that of the color filter. In a cross section perpendicular to the principal surface P, the color filter has a reverse tapered shape. The second color and the third color may be the same color or different colors. The color filter may be shaped such that a side surface in contact with the first layer and a side surface in contact with the second layer have a reverse tapered shape.

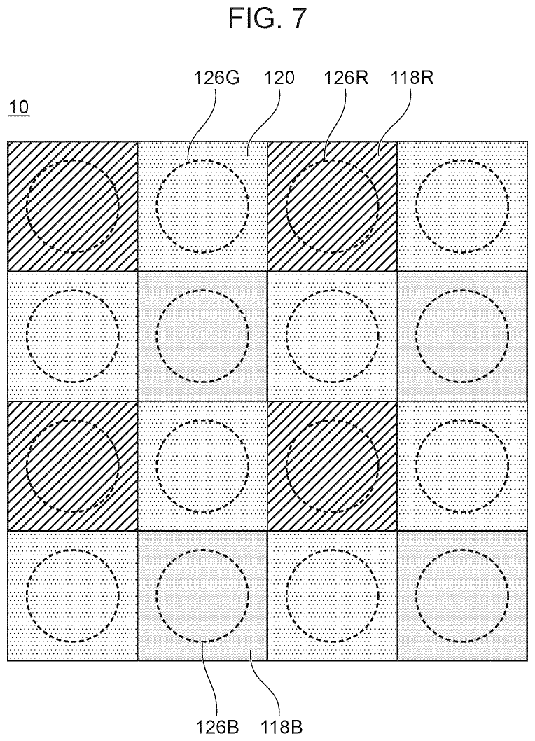

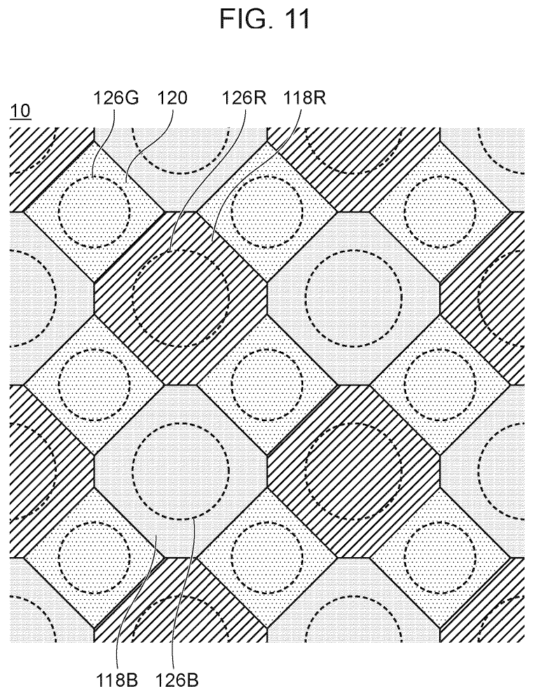

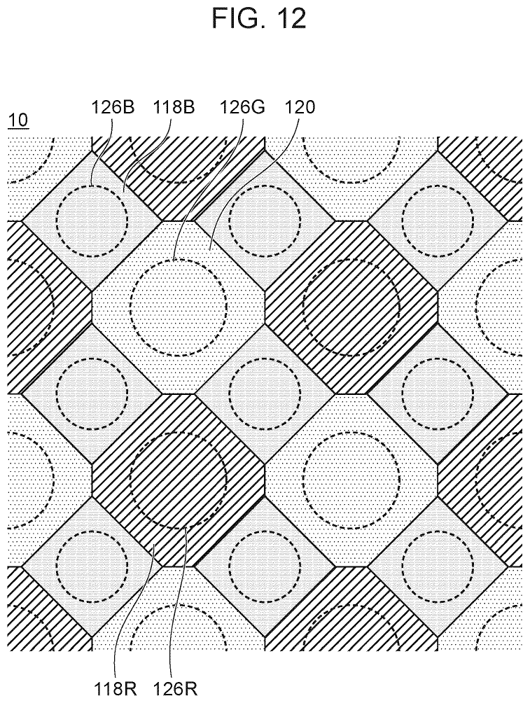

FIGS. 7 to 12 illustrate examples of arrangements of color filters 118 and first layers 120. Referring to FIGS. 7 to 10, in a plan view relative to the principal surface P, color filters 118R, color filters 118B, and first layers 120 have a rectangular outer shape. Referring to FIGS. 11 and 12, in a plan view relative to the principal surface P, color filters 118R, color filters 118B, and first layers 120 have a rectangular or octagonal outer shape.

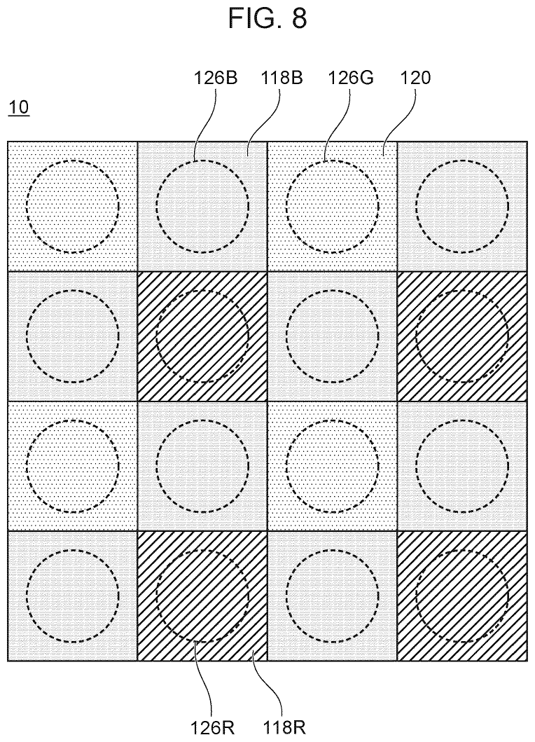

In the examples illustrated in FIGS. 8 to 10 and FIG. 12, the color filters 118 have two side surfaces in contact with the first layers 120. Therefore, the organic light-emitting devices of these examples have a high light extraction efficiency.

In the examples illustrated in FIGS. 7 and 11, the color filters 118R and the color filters 118B both have four side surfaces in contact with the first layers 120, thus providing two types of organic light-emitting elements including the color filters 118R and the color filters 118B both having a high light extraction efficiency.

In the examples illustrated in FIGS. 7, 8, 11, and 12, the number of light-emitting elements 20R including the color filters 118R (the number of light-emitting elements 20B including the color filters 118B) differs from the number of light-emitting elements 20 including the first layers 120. More specifically, in the examples illustrated in FIGS. 7 and 11, the number of light-emitting elements 20R including the color filters 118R (the number of light-emitting elements 20B including the color filters 118B) is less than the number of organic light-emitting elements including the first layers 120. In the examples illustrated in FIGS. 8 and 12, the number of light-emitting elements 20R including the color filters 118R (the number of light-emitting elements 20B including the color filters 118B) is greater than the number of organic light-emitting elements including the first layers 120. Also in this case, when the color filters 118 have a plurality of side surfaces in contact with the first layers 120, the extraction efficiency of the light emitted from the organic light-emitting elements including the color filters 118 can be increased. In the example illustrated in FIG. 11, the ratio of the region in which the side surfaces of the color filters 118R or the color filters 118B are in contact with the first layers 120 is 60% or more, thereby providing increased light extraction efficiency.

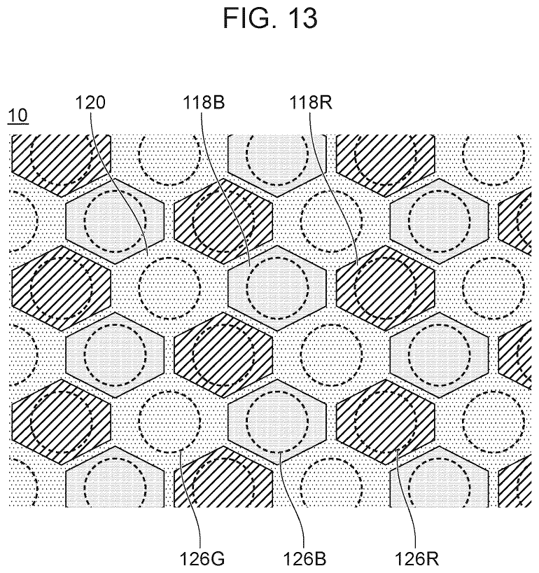

In the example illustrated in FIG. 13, color filters 118 and first layers 120 have the same arrangement as that in the example illustrated in FIG. 6. However, the first layers 120 corresponding to the light-emitting sections are not separated from each other but are connected to each other. In other words, the color filter 118R and the color filter 118B are surrounded by the first layers 120. Since the color filters 118R and the color filters 118B are surrounded by the first layers 120, the ratio of the region in which the side surfaces of the color filters 118R and the color filters 118B are in contact with the first layers 120 is 100%, thereby providing significantly increased light extraction efficiency.

As described above, in each of the color filters 118R and the color filters 118B, the intensity and color purity of oblique light differ between the direction of contact with the first layer 120 and the direction of contact with another color filter 118, and therefore the viewing angle characteristics may differ. The viewing angle characteristics of a display apparatus may preferably have a high degree of symmetry to increase the display quality.

In the example illustrated in FIG. 6, as described above, each of the color filters 118R and the color filters 118B has three side surfaces in contact with the first layers 120, and the viewing angle characteristics thereof have a three-fold rotational symmetry. In the example illustrated in FIG. 5, each of the color filters 118R and the color filters 118B is in contact with the first layer 120 in only one direction, and therefore the viewing angle characteristics thereof lack rotational symmetry. Thus, the arrangement illustrated in FIG. 6 has viewing angle characteristics with a higher level of symmetry than the arrangement illustrated in FIG. 5, and therefore provides a higher display quality.

Similarly, the viewing angle characteristics have a two-fold rotational symmetry in the examples illustrated in FIGS. 8 to 10 and FIG. 12 and a four-fold rotational symmetry in the examples illustrated in FIGS. 7 and 11. Thus, the arrangement illustrated in FIG. 11 has viewing angle characteristics with a higher level of symmetry than the arrangement illustrated in FIG. 6, and is therefore preferred in terms of improving display quality. In the example illustrated in FIG. 13, the color filters 118R and the color filters 118B are surrounded by the first layers 120. This is preferable because the differences in the viewing angle characteristics can be reduced in all directions.

The first layers 120 may cause a greater amount of moisture permeation than the color filters 118. When, in particular, the first layers 120 are air layers or transparent resin layers, the first layers 120 may cause a greater moisture permeation than the color filters 118.

Assume that the amount of moisture permeation in a high-humidity environment is to be reduced to increase the reliability of the light-emitting device. In such a case, when the first layers 120 are formed to extend continuously from end portions to a central portion of the display region, as illustrated in FIG. 5, the first layers 120 may serve as moisture permeation paths. In contrast, in the examples illustrated in FIGS. 6 to 11, the first layers 120 do not extend continuously from end portions to a central portion of the display region. Therefore, the first layers 120 do not easily serve as moisture permeation paths, and the amount of moisture permeation can be reduced. For this reason, the arrangements in the examples illustrated in FIGS. 6 to 11 are preferred in terms of increasing reliability because the amount of moisture permeation can be reduced.

### <Applications>

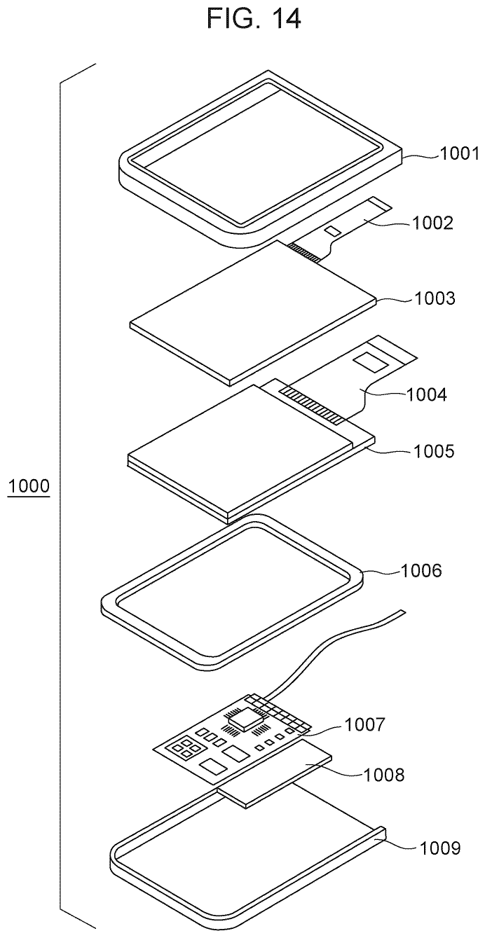

Applications in which a light-emitting device 10 according to the present embodiment is applied to a display apparatus, a photoelectric conversion apparatus, an electronic apparatus, a lighting apparatus, a moving body, and a wearable device will be described with reference to FIGS. 14 to 18.

FIG. 14 is a schematic diagram illustrating a display apparatus 1000 as an example of a display apparatus according to the present embodiment. The display apparatus 1000 may include a touch panel 1003, a display panel 1005, a frame 1006, a circuit board 1007, and a battery 1008, which are disposed between an upper cover 1001 and a lower cover 1009. The display panel 1005 is a display unit including the light-emitting device 10 according to any one of the first to fourth embodiments, and performs a display operation using light emitted from the light-emitting device 10. The touch panel 1003 and the display panel 1005 are respectively connected to flexible printed circuits (FPCs) 1002 and 1004. A control circuit including transistors is printed on the circuit board 1007. The control circuit performs various control operations, such as an operation of controlling the display panel 1005. The battery 1008 may be omitted when the display apparatus is not a mobile device, and may be provided at a different location even when the display apparatus is a mobile device. The display apparatus 1000 may include three types of color filters corresponding to red, green, and blue. The color filters may be in a delta arrangement.

The display apparatus 1000 may be used as a display unit of a mobile terminal. In such a case, the display apparatus 1000 may have both a display function and an operating function. The mobile terminal may be, for example, a mobile phone, such as a smartphone, a tablet, or a head-mounted display.

The display apparatus 1000 may be used as a display unit of an imaging apparatus including an optical unit having a plurality of lenses and an imaging element that receives light that has passed through the optical unit. The imaging apparatus may include the display unit to display information acquired by the imaging element (for example, an image captured by the imaging element). The display unit may be exposed to the outside of the imaging apparatus or disposed in a finder. The imaging apparatus may be, for example, a digital camera or a digital video camera.

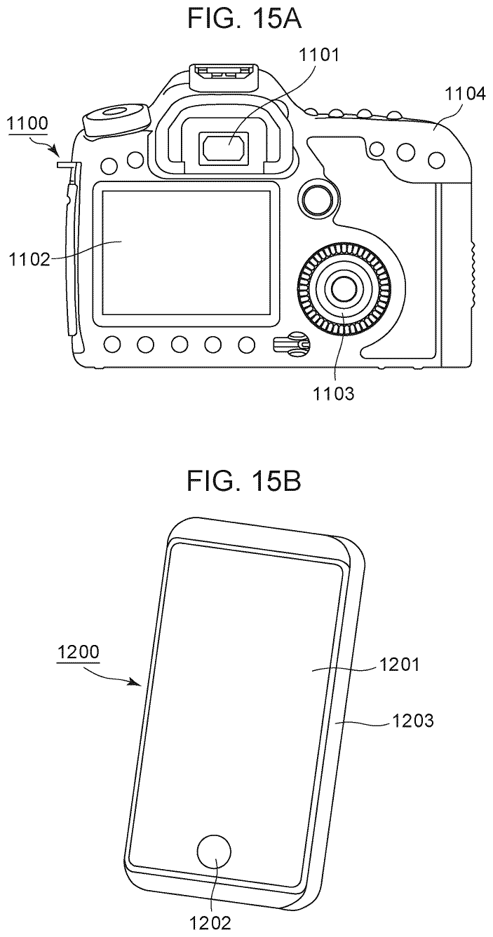

FIG. 15A is a schematic diagram illustrating an imaging apparatus 1100 as an example of an imaging apparatus according to the present embodiment. The imaging apparatus 1100 may include an electronic viewfinder 1101, a back display 1102, an operation unit 1103, and a housing 1104. The electronic viewfinder 1101 includes a display apparatus including the light-emitting device 10 according to any one of the first to fourth embodiments, and performs a display operation using light emitted from the light-emitting device 10. In such a case, the display apparatus may display, for example, environmental information and imaging instructions in addition to an image to be captured. The environmental information may include the intensity and direction of external light, the moving speed of a subject, and the possibility of the subject being blocked by an object.

It is desirable to display the information as quickly as possible because the moment suitable for imaging lasts only for a short time. Therefore, a display apparatus including organic light-emitting elements, which have a high response speed, may be preferably used. The display apparatus including the organic light-emitting elements is more suitable than a liquid crystal display apparatus or the like when high display speed is required.

The imaging apparatus 1100 includes an optical unit. The optical unit includes a plurality of lenses, and focuses light on an imaging element disposed in the housing 1104. The relative positions of the lenses can be adjusted to adjust the focal points. This operation can be performed automatically.

The imaging apparatus 1100 may be referred to as a photoelectric conversion apparatus. Instead of capturing images one by one, the photoelectric conversion apparatus may use a method of capturing an image by detecting a difference from the previous image or by extracting a portion of an image being recorded.

FIG. 15B is a schematic diagram illustrating an electronic apparatus 1200 as an example of an electronic apparatus according to the present embodiment. The electronic apparatus 1200 includes a display unit 1201, an operation unit 1202, and a housing 1203. The display unit 1201 includes a display apparatus including the light-emitting device 10 according to any one of the first to fourth embodiments, and performs a display operation using light emitted from the light-emitting device 10. In the electronic apparatus 1200, the housing 1203 may contain a circuit, a printed board having the circuit, a battery, and a communication unit that communicates with the outside. The operation unit 1202 may be a button or a touch-panel reaction unit. The operation unit may be a biometric identification unit that recognizes fingerprints and unlocks the device, for example. The electronic apparatus including the communication unit may also be regarded as a communication apparatus. The electronic apparatus may also include a lens and an imaging element to provide a camera function. The display unit displays an image captured by using the camera function. The electronic apparatus may be, for example, a smartphone or a notebook personal computer.

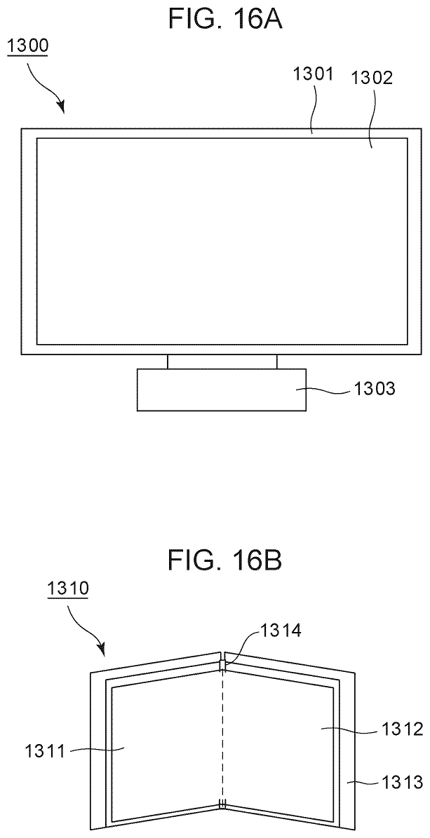

FIG. 16A is a schematic diagram illustrating a display apparatus 1300 as an example of a display apparatus according to the present embodiment. The display apparatus 1300 is, for example, a television monitor or a personal computer (PC) monitor. The display apparatus 1300 includes a frame 1301, a display unit 1302, and a base 1303 that supports the frame 1301 and the display unit 1302. The display unit 1302 includes a display apparatus including the light-emitting device 10 according to any one of the first to fourth embodiments, and performs a display operation using light emitted from the light-emitting device 10. The structure of the base 1303 is not limited to that illustrated in FIG. 16A. The bottom side of the frame 1301 may function as the base 1303. The frame 1301 and the display unit 1302 may be curved. In such a case, the radius of curvature may be 5000 mm or more and 6000 mm or less.

FIG. 16B is a schematic diagram illustrating a display apparatus 1310 as another example of a display apparatus according to the present embodiment. The display apparatus 1310 is a foldable display apparatus that is capable of being folded. The display apparatus 1310 includes a first display unit 1311, a second display unit 1312, a housing 1313, and a folding point 1314. Each of the first display unit 1311 and the second display unit 1312 includes a display apparatus including the light-emitting device 10 according to any one of the first to fourth embodiments, and performs a display operation using light emitted from the light-emitting device 10. The first display unit 1311 and the second display unit 1312 may constitute a single seamless display apparatus. The first display unit 1311 and the second display unit 1312 may be sectioned from each other at the folding point. The first display unit 1311 and the second display unit 1312 may display different images. Alternatively, the first display unit 1311 and the second display unit 1312 may display a single image together.

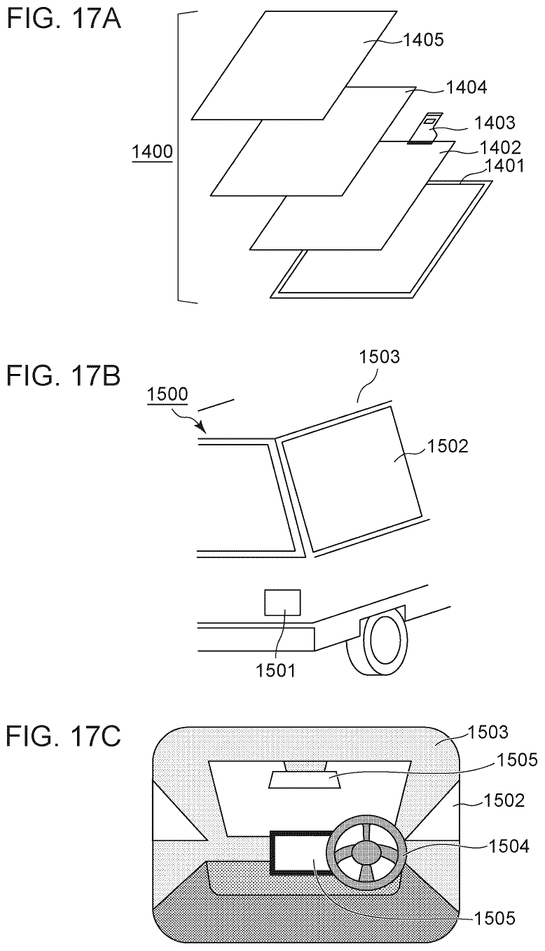

FIG. 17A is a schematic diagram illustrating a lighting apparatus 1400 as an example of a lighting apparatus according to the present embodiment. The lighting apparatus 1400 includes a housing 1401, a light source 1402, a circuit board 1403, an optical film 1404, and a light diffuser 1405. The light source 1402 includes the light-emitting device 10 according to any one of the first to fourth embodiments. The optical film 1404 may be a filter (optical filter) that improves color rendering properties of the light source 1402. The light diffuser 1405 is capable of effectively diffusing light from the light source 1402 to deliver light to a large area for illumination or the like. The optical film 1404 and the light diffuser 1405 may be provided on the light emission side of the lighting apparatus 1400. A cover may be provided on an outermost portion as necessary.

The lighting apparatus 1400 is, for example, an indoor lighting apparatus. The color of light emitted from the lighting apparatus 1400 may be white, neutral white, or another color (any color from blue to red). White is a color with a color temperature of 4200 K, and neutral white is a color with a color temperature of 5000 K. The lighting apparatus 1400 may have a light control circuit that controls the color of light emitted by the lighting apparatus 1400. The lighting apparatus 1400 may include a power supply circuit connected to the light source 1402. The power supply circuit is a circuit that converts an alternating current voltage into a direct current voltage. The lighting apparatus 1400 may include a color filter. The lighting apparatus 1400 may include a heat dissipation unit. The heat dissipation unit dissipates heat in the apparatus to the outside of the apparatus and is made of, for example, a metal with high specific heat or liquid silicon.

FIG. 17B is a schematic diagram illustrating an automobile 1500 as an example of a moving body according to the present embodiment. The automobile 1500 may include a taillight 1501 as an example of a lamp. The taillight 1501 may be turned on in response to a brake operation or the like.

The taillight 1501 includes the light-emitting device 10 according to any one of the first to fourth embodiments. The taillight 1501 may include a protective member for protecting the light-emitting device. The protective member may be made of any material that is moderately strong and transparent, and may be made of polycarbonate or the like. The polycarbonate may be mixed with a furandicarboxylic acid derivative, an acrylonitrile derivative, or the like.

The automobile 1500 may include a vehicle body 1503 and a window 1502 attached to the vehicle body 1503. The window 1502 may be a transparent display unless the window 1502 is a window for checking the front and rear of the automobile 1500. The transparent display includes a display apparatus including the light-emitting device 10 according to the first embodiment or second embodiment, and performs a display operation using light emitted from the light-emitting device 10. In this case, constituent materials, such as electrodes, of the light-emitting device are transparent members.

As illustrated in FIG. 17C, the automobile 1500 includes a steering wheel 1504 for controlling the moving direction of the moving body and display units 1505 for displaying a map, the position of the moving body, the turning direction, and the like, and that is installed in the vehicle body 1503. The display units 1505 may include the organic light-emitting device according to any one of the first to fourth embodiments.

The moving body according to the present embodiment includes a driving force generator that generates driving force used mainly to move the moving body and/or a rotating body used mainly to move the moving body. The driving force generator may be an engine, a motor, or the like. The rotating body may be a tire, a wheel, a screw of a ship, or the like. More specifically, the moving body may be a bicycle, an automobile, a train, a ship, an aircraft, a drone, or the like. The moving body may include a body, and may also include a lamp provided on the body or a display unit provided on the body. The lamp may emit light to indicate the position of the body. The lamp may include the light-emitting device according to the present embodiment.

The display apparatus according to the present embodiment includes a display apparatus including the light-emitting device 10 according to any one of the first to fourth embodiments, and may be applied to, for example, a wearable device, such as smart glasses, an HMD, or smart contact lenses. The display apparatus according to the present embodiment may also be applied to a system including a wearable device or the like. An imaging display apparatus used as a wearable device includes an imaging apparatus capable of photoelectrically converting visible light and a display apparatus capable of emitting visible light.

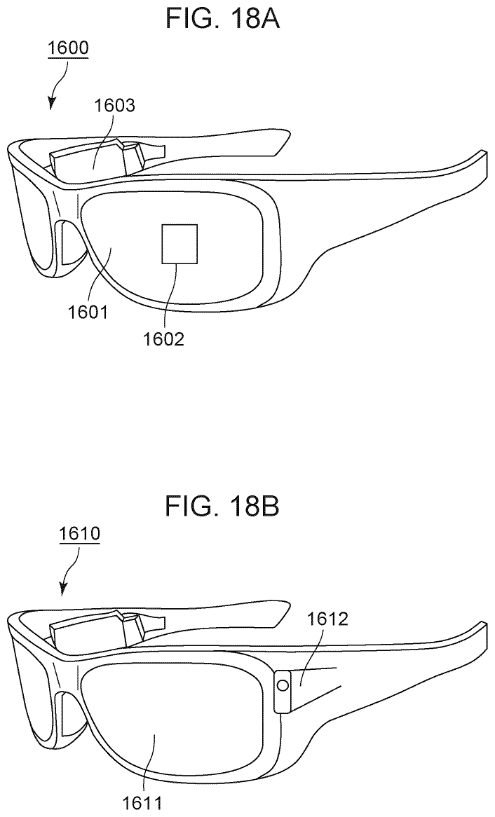

FIG. 18A is a schematic diagram illustrating eyeglasses 1600 (smart glasses) as an example of a wearable device according to the present embodiment. An imaging apparatus 1602, such as a complementary metal-oxide-semiconductor (CMOS) sensor or a single-photon avalanche photodiode (SPAD), is provided on the front side of a lens 1601 of the eyeglasses 1600. A display apparatus including the light-emitting device 10 according to any one of the first to fourth embodiments is provided on the back side of the lens 1601. The display apparatus performs a display operation using light emitted from the light-emitting device 10.

The eyeglasses 1600 further include a controller 1603. The controller 1603 serves as a power supply that supplies electric power to the imaging apparatus 1602 and the above-described display apparatus. The controller 1603 controls the operations of the imaging apparatus 1602 and the display apparatus. The lens 1601 includes an optical system for collecting light in the imaging apparatus 1602.

FIG. 18B is a schematic diagram illustrating eyeglasses 1610 (smart glasses) as another example of a wearable device according to the present embodiment. The eyeglasses 1610 include a controller 1612. The controller 1612 includes an imaging apparatus corresponding to the imaging apparatus 1602 and a display apparatus according to the present embodiment. A lens 1611 includes an optical system for projecting light from the imaging apparatus included in the controller 1612 and the display apparatus, and projects an image onto the lens 1611. The controller 1612 serves as a power supply that supplies electric power to the imaging apparatus and the display apparatus, and also controls the operations of the imaging apparatus and the display apparatus.

The controller may include a line-of-sight detector that detects the line of sight of a wearer who wears the eyeglasses 1610. Infrared radiation may be used to detect the line of sight. An infrared-light-emitting unit emits infrared light toward an eyeball of a user who is looking at the displayed image. The infrared light emitted toward and reflected by the eyeball is detected by an imaging unit including a light-receiving element to capture an image of the eyeball. A reduction unit may be provided to reduce light from the infrared-light-emitting unit toward the display unit in plan view, thereby reducing the degradation of the quality of the image projected from the display apparatus onto the lens 1611. The line of sight of the user with respect to the displayed image is detected based on the image of the eyeball captured by using the infrared light. Methods to detect the line of sight using the captured image of the eyeball may include the line of sight can be detected based on a Purkinje image obtained by the reflection of the irradiation light at the cornea. More specifically, a line-of-sight detection process is performed based on the pupil-cornea reflection method. By using the pupil-cornea reflection method, a line-of-sight vector representing the orientation (rotation angle) of the eyeball is calculated based on an image of the pupil and a Purkinje image included in the captured eyeball image, so that the line of sight of the user is detected.

When the display control is performed based on the visual recognition detection (line-of-sight detection), the light-emitting device 10 according to any one of the first to fourth embodiments may be suitably applied to smart glasses including an imaging apparatus that captures the image of the outside environment. The smart glasses are capable of displaying the captured image of the outside environment in real time.

The above-described display apparatus may include an imaging apparatus including a light-receiving element and control a display image based on the information of the user's line of sight obtained from the imaging apparatus. More specifically, a first viewing region at which the user looks and a second viewing region other than the first viewing region are determined based on the line-of-sight information. The first viewing region and the second viewing region may be determined by the controller included in the display apparatus, or be determined by an external controller and received by the display apparatus. The display resolution in the display region of the display apparatus may be controlled such that the display resolution is higher in the first viewing region than in the second viewing region. In other words, the resolution may be lower in the second viewing region than in the first viewing region.

Alternatively, the display region may include a first display region and a second display region different from the first display region, and a region with higher priority may be selected from the first display region and the second display region based on the line-of-sight information. The first display region and the second display region may be determined by the controller included in the display apparatus, or be determined by an external controller and received by the display apparatus. The resolution in the region with higher priority may be higher than the resolution in the region other than the region with higher priority. In other words, the resolution in the region with lower priority can be reduced.

Artificial intelligence (AI) may be used to determine the first display region or the region with higher priority. The AI may be configured to use images of eyeballs and the actual directions of sight of the eyeballs in the images as training data and estimate the angle of the line of sight and the distance to an object on the line of sight based on an image of the eyeball. AI programs may be included in the display apparatus, the imaging apparatus, or an external device. When the external device has the AI programs, the AI programs may be transmitted to the display apparatus via communication.

### EXAMPLES

The present disclosure will now be described by way of examples. However, the present disclosure is not limited to the examples.

### Example 1

First, aluminum, silicon oxide, and ITO layers were successively formed on a substrate, and patterns were formed to form anodes corresponding to light-emitting elements. In this example, the top surface of the aluminum layer serves as a first reflective surface. The anodes were in a delta arrangement, as illustrated in FIG. 5. The thickness of the silicon oxide layer was 230 nm in red pixels, 160 nm in green pixels, and 110 nm in blue pixels. The thickness of the ITO layer was 50 nm.

Next, banks were formed to cover the ITO anodes. The banks were formed using silicon oxide and had a film thickness of 65 nm. Openings were formed in the banks at the central regions of the anodes so that the anodes were exposed. In this example, the openings at which the anodes were exposed had a circular shape with a radius of 1.2 μm. The distance between the centers of the adjacent openings was 4.2 μm. As described above, the openings correspond to the light-emitting regions of the organic light-emitting elements.

After the banks were formed, an organic compound layer was formed on the anodes and the banks. More specifically, a layer of compound 1 described below with a thickness of 3 nm was formed as a hole injection layer. A layer of compound 2 with a thickness of 15 nm was formed on the hole injection layer as a hole transport layer. A layer of compound 3 with a thickness of 10 nm was formed on the hole transport layer as an electron blocking layer. Next, a first light-emitting layer with a thickness of 10 nm was formed such that the weight ratio of compound 4 serving as the host material was 97% and the weight ratio of compound 5 serving as a light-emitting dopant was 3%. Next, a second light-emitting layer with a thickness of 10 nm was formed such that the weight ratio of compound 4 serving as the host material was 98% and the weight ratios of compound 6 and compound 7 serving as a light-emitting dopant were 1%. Next, a layer of compound 8 with a thickness of 110 nm was formed on the second light-emitting layer as an electron transport layer. Next, a layer of lithium fluoride with a thickness of 1 nm was formed on the electron transport layer as an electron injection layer.

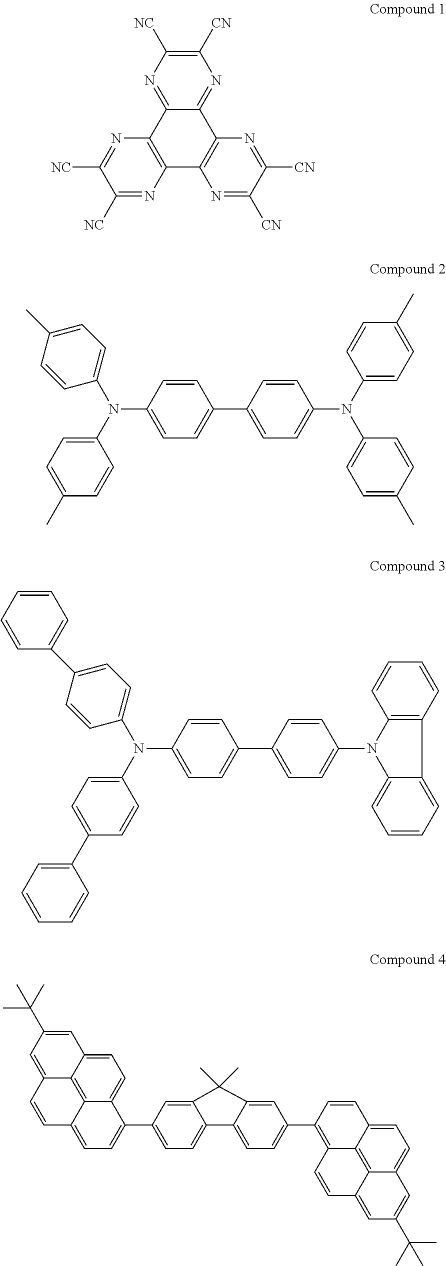

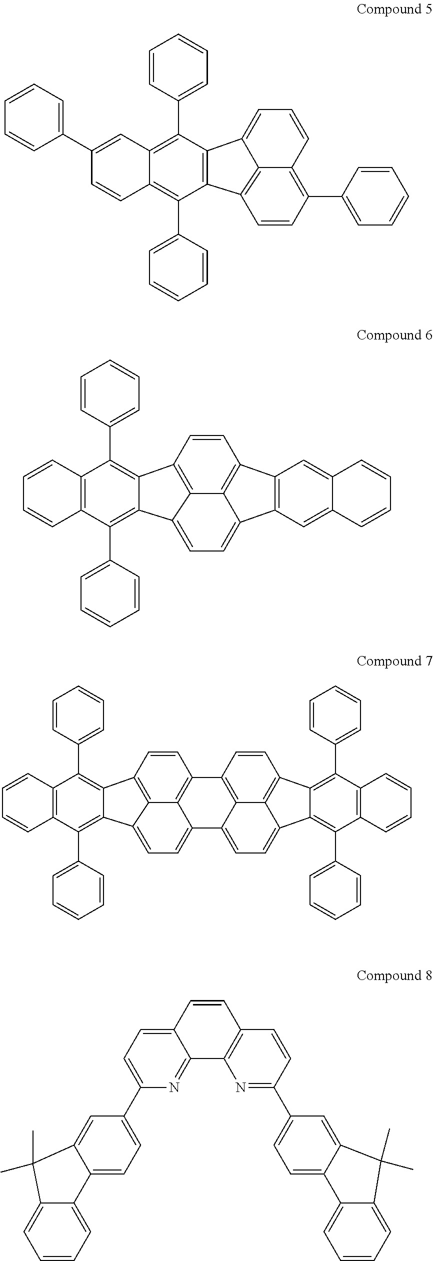

Next, an Mg—Ag alloy layer with a thickness of 10 nm was formed on the organic compound layer as a cathode. The ratio between Mg and Ag was 1:1. In this example, the cathode served as a second reflective layer. As described above, the optical distance from the light-emitting layer to the first reflective surface and the distance from the first reflective surface to the second reflective surface were adjusted for each pixel so that light emitted from the light-emitting unit had a peak in a red wavelength range in a red pixel, in a green wavelength range in a green pixel, and in a blue wavelength range in a blue pixel.

Next, a sealing layer (protective layer) was formed on the cathode by CVD. The sealing layer was made of SiN with a refractive index of 1.97 and had a thickness of 2.0 μm.

Next, a planarization layer with a refractive index of 1.55 and a thickness of 0.2 μm was formed on the sealing layer by spin coating.

Next, color filters with a refractive index of 1.65 and a thickness of 1.6 μm were formed on the planarization layer.

The color filters included color filters for transmitting red light and color filters for transmitting blue light. Side surfaces of the color filters in contact with low-refractive-index layers (first layers) had a reverse tapered shape to satisfy θ=10 degrees.

Next, transparent resin layers with a refractive index of 1.35 and a thickness of 1.6 μm was formed as the low-refractive-index layers.

After the color filters and the low-refractive-index layers were formed, the planarization layer 116 with a refractive index of 1.55 and a thickness of 0.2 μm was formed on the color filters and the low-refractive-index layers by spin coating.

In this example, the refractive index n₁ of the color filters was 1.65 and the refractive index n₂ of the low-refractive-index layers was 1.35, so that n₂/n₁=0.818. In addition, H₁ was 0.9 μm and V₁ was 3.8 μm, so that V₁/(H₁²+V₁²)^{1/2}=0.973. Therefore, the organic light-emitting device of this example satisfies n₂/n₁<V₁/(H₁²+V₁²)^{1/2}.

In this example, V₂ was 2.2 μm and H₂ was 3.02 μm, so that Arctan (H₂/V₂)=Arctan (1.37)=54 degrees. In addition, in this example, θ=10 degrees. Therefore, the organic light-emitting device of this example satisfied θ<Arctan (H₂/V₂), and also satisfied 2θ<Arctan (H₂/V₂).

In the organic light-emitting device of this example, the side surfaces of the color filters adjacent to the low-refractive-index layers had a reverse tapered shape, so that the light condensing effect was obtained. As a result, the light extraction efficiency of the organic light-emitting elements in the red and blue pixels was improved.

### Example 2

Organic light-emitting elements were formed similarly to Example 1, and then an optical member (lenses) with a refractive index of 1.52 was formed on the planarization layer by an exposure process and a developing process. The optical member was thickest (1.5 μm) at the apices of the optical member, and the cross-sectional shape thereof included portions of substantially spherical (circular) shapes. Other structures were the same as those in Example 1.

Since the optical member was provided, the organic light-emitting elements of this example were capable of providing the light condensing effect over 360 degrees. Thus, organic light-emitting elements with a high light extraction efficiency were obtained.

As described above, the organic light-emitting elements according to the present disclosure have a high light extraction efficiency.

The present disclosure can provide a light-emitting device with a high light extraction efficiency.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims priority to and the benefit of Japanese Patent Application No. 2024-186679, filed Oct. 23, 2024, which is hereby incorporated by reference herein in its entirety.

What is claimed is:

1. A light-emitting device comprising:
a first light-emitting element and a second light-emitting element provided above a surface of a substrate, the second light-emitting element being adjacent to the first light-emitting element,
wherein each of the first light-emitting element and the second light-emitting element includes a first electrode, a light-emitting layer, and a second electrode,
wherein the first light-emitting element includes a color filter provided above the second electrode, and configured to transmit first light,
wherein the second light-emitting element includes a first layer above the second electrode, the first layer having a refractive index less than a refractive index of the color filter and configured to transmit second light,
wherein the color filter has a reverse tapered shape in a cross section perpendicular to the surface,
wherein the first light-emitting element includes a first light-emitting region, and the second light-emitting element includes a second light-emitting region, and
wherein, in the cross section perpendicular to the surface, when a first point is closest to the second light-emitting element and farthest from the surface in the reverse tapered shape of the color filter, a second point is in the first light-emitting region closest to the second light-emitting region and is on the second electrode, a first line passes through the first point parallel to the surface, a second line passes through the first point perpendicular to the surface:
$${n}_{2} / {n}_{1} < {V}_{1} / {( {H}_{1}^{2} + {V}_{1}^{2} )}^{1 / 2} ,$$
with V₁ being a height from an interface between the light-emitting layer and the second electrode in the first light-emitting region to the first line, H₁ being a width from the second point to the second line, n₁ being the refractive index of the color filter, and n₂ being the refractive index of the first layer.

2. The light-emitting device according to claim 1, wherein the first layer is made of a transparent resin.

3. The light-emitting device according to claim 1, wherein the first layer is a color filter.

4. The light-emitting device according to claim 1, wherein the first layer is formed as an air layer.

5. The light-emitting device according to claim 1, wherein, in the cross section perpendicular to the surface, when a first width is a width of the color filter on a top surface of the color filter, a second width is a width of the color filter on a bottom surface of the color filter, and a third width is a width of the color filter between the top surface and the bottom surface of the color filter, and
wherein the third width is greater than the first width and the second width.

6. The light-emitting device according to claim 1, wherein, in the cross section perpendicular to the surface, when a first width is a width of the color filter on a top surface of the color filter, a second width is a width of the color filter on a bottom surface of the color filter, and a third width is a width of the color filter between the top surface and the bottom surface of the color filter, and
wherein the third width is less than the first width and the second width.

7. The light-emitting device according to claim 1, wherein:
n₁−n₂>0.2.

8. The light-emitting device according to claim 1, wherein the first layer has a tapered shape.

9. The light-emitting device according to claim 1, wherein, in the cross section perpendicular to the surface, when a third point is closest to the surface in the reverse tapered shape of the color filter, a fourth point is in the first light-emitting region farthest from the second light-emitting region and is on the second electrode, a third line passing through the third point perpendicular to the surface, a fourth line passing through the third point parallel to the surface:
θ<Arctan(H₂/V₂),
with V₂ being a height from the fourth point to the fourth line, H₂ being a width from the fourth point to the third line, and θ being an angle between a straight line connecting the first point and the third point and the second line, with the third point disposed between the first point and the fourth point in a plan view relative to the surface.

10. The light-emitting device according to claim 9, wherein:
$$2 θ < Arctan ( {H}_{2} / {V}_{2} ) .$$

11. The light-emitting device according to claim 1, wherein:
the surface is a principal surface of the substrate,
each of the first light-emitting element and the second light-emitting element includes a reflective layer between the substrate and the first electrode, and
a distance between the reflective layer and the first electrode included in the first light-emitting element differs from a distance between the reflective layer and the first electrode included in the second light-emitting element.

12. The light-emitting device according to claim 1, wherein each of the first light-emitting element and the second light-emitting element includes a reflective layer between the substrate and the light-emitting layer, and
wherein a distance between the reflective layer and the light-emitting layer included in the first light-emitting element differs from a distance between the reflective layer and the light-emitting layer included in the second light-emitting element.

13. The light-emitting device according to claim 1, further comprising:
a third light-emitting element,
wherein the third light-emitting element includes the first electrode, the light-emitting layer, and the second electrode,
wherein the third light-emitting element and the first light-emitting element are adjacent to each other, and
wherein the third light-emitting element includes a second layer above the second electrode, the second layer transmitting third light and having a refractive index less than a refractive index of the color filter.

14. The light-emitting device according to claim 1, wherein the second light has an emission peak in the range of 490 nm or more and 550 nm or less.

15. A light-emitting device comprising:
a first light-emitting element and a second light-emitting element above a surface of a substrate, the second light-emitting element being adjacent to the first light-emitting element,
wherein each of the first light-emitting element and the second light-emitting element includes a first electrode, a light-emitting layer, and a second electrode,
wherein the first light-emitting element includes a color filter provided above the second electrode, the color filter configured to transmit first light,
wherein the second light-emitting element includes a first layer provided above the second electrode, the first layer configured to transmit second light and being made of a transparent resin, and
wherein the color filter has a reverse tapered shape in a cross section perpendicular to the surface.

16. The light-emitting device according to claim 15, wherein the first layer has a tapered shape.

17. A display apparatus comprising:
a display unit including the light-emitting device according to claim 1; and
a housing in which the display unit is provided.

18. A photoelectric conversion apparatus comprising:
an imaging element configured to receive light; and
a display unit configured to display an image captured by the imaging element,
wherein the display unit is the light-emitting device according to claim 1.

19. An electronic apparatus comprising:
a display unit including the light-emitting device according to claim 1;
a housing in which the display unit is provided; and
a communication unit that is provided in the housing and is configured to communicate with an outside of the electronic apparatus.

20. A wearable device comprising:
a display unit including the light-emitting device according to claim 1;
an optical system that collects light of the display unit; and
a controller that controls an operation of the display unit.
